(19) United States
(12) Patent Application Publication
(10) Pub. No.: US 2019/0214514 A1
(43) Pub. Date: Jul. 11, 2019

(54) SEMICONDUCTOR ELEMENT

(71) Applicant: LG INNOTEK CO., LTD., Seoul (KR)

(72) Inventor: Eun Ju HONG, Seoul (KR)

(73) Assignee: LG INNOTEK CO., LTD., Seoul (KR)

(21) Appl. No.: 16/315,521

(22) PCT Filed: Jul. 5, 2017
(86) PCT No.: PCT/KR2017/007134

§ 371 Date: Jan. 4, 2019

(30) Foreign Application Priority Data
Jul. 5, 2016 (KR) 10-2016-0084895
Jun. 5, 2017 (KR) 10-2017-0069659

(51) Int. Cl. H01L 31/0352; H01L 31/02; H01L 31/0203; H01L 31/0216; H01L 31/167; H01L 31/107

(52) U.S. Cl. CPC H01L 31/035281; H01L 31/02005; H01L 31/107; H01L 31/02165; H01L 31/167; H01L 31/0203

(57) ABSTRACT

An embodiment provides a semiconductor element, which comprises: a substrate; and a semiconductor structure disposed on the substrate, wherein the semiconductor structure comprises a first conductive semiconductor layer, a second conductive semiconductor layer, and a light absorption layer disposed between the first conductive semiconductor layer and the second conductive semiconductor layer, and the light absorption layer has a value of 1.2 to 1.5 as a ratio of a maximum outer periphery length of an upper surface thereof with respect to a maximum area of the upper surface thereof.

### TECHNICAL FIELD

Embodiments relate to a semiconductor element.

### BACKGROUND ART

Semiconductor elements including compounds such as GaN and AlGaN have many merits such as wide and adjustable band gap energy and thus may be variously used as light emitting elements, light receiving elements, various kinds of diodes, or the like.

In particular, light emitting elements such as a light emitting diode or a laser diode using group III-V or II-VI compound semiconductor materials may implement various colors such as red, green, blue, and ultraviolet rays due to the development of thin film growth technology and element materials, and may implement efficient white light rays by using fluorescent materials or combining colors. These light emitting elements also have advantages with respect to low power consumption, semi-permanent life span, fast response time, safety, and environmental friendliness compared to conventional light sources such as a fluorescent lamp, an incandescent lamp, or the like.

In addition, when light receiving elements such as optical detectors or solar cells are produced using group III-V or II-VI compound semiconductor materials, a photocurrent may be generated by light absorption in various wavelength ranges through development of element materials. Thus, light may be used in various wavelength ranges from gamma rays to radio wavelength regions. Also, the light receiving elements have the advantages of fast response time, stability, environmental friendliness, and ease of adjustment of element materials and may be easily used to power control or microwave circuits or communication modules.

Accordingly, application of semiconductor elements are being extended to the transmission modules of optical communication means, light emitting diode backlights substituted for cold cathode fluorescent lamps (CCFL) forming the backlights of a liquid crystal display (LCD) device, white light emitting diode lamps to be substituted for fluorescent bulbs or incandescent bulbs, car headlights, traffic lights, and sensors for detecting gas or fire. In addition, the application of semiconductor elements may also be extended to high-frequency application circuits or other power control devices and communication modules.

In particular, a light receiving element absorbs light and generate a photocurrent, and thus there is a need to improve light sensitivity.

Also, research on a semiconductor element, which is the aforementioned light receiving element, has been conducted in order to improve light sensing sensitivity.

### DETAILED DESCRIPTION OF THE INVENTION

### Technical Problem

An embodiment provides a flip-chip type semiconductor element.

An embodiment also provides a semiconductor element with a decreased dark current.

An embodiment also provides a semiconductor element with improved reaction sensitivity.

Problems to be solved in the embodiments are not limited thereto and include the following technical solutions and also objectives or effects understandable from the embodiments.

### Technical Solution

A semiconductor element according to an embodiment of the present invention includes a substrate; and a semiconductor structure disposed on the substrate. The semiconductor structure includes a first conductive semiconductor layer, a second conductive semiconductor layer, and a light absorbing layer disposed between the first conductive semiconductor layer and the second conductive semiconductor layer. The light absorbing layer has a ratio of a maximum outer length of an upper surface to a maximum area of the upper surface ranging from 1.25 to 1.5.

The upper surface of the light absorbing layer may be circular.

The semiconductor element may further include a filter layer between the substrate and the first conductive semiconductor layer.

The semiconductor element may further include a first electrode disposed on the first conductive semiconductor layer and electrically connected to the first conductive semiconductor layer; and a second electrode disposed on the second conductive semiconductor layer and electrically connected to the second conductive semiconductor layer.

The minimum distance between the first electrode and the upper surface of the light absorbing layer may be 5 μm or greater.

An upper surface of the second electrode may have the same area as an upper surface of the second conductive semiconductor layer.

The first electrode may be spaced apart from the light absorbing layer and shaped to surround the light absorbing layer.

The first electrode may be formed in the shape of tongs.

The semiconductor element may further include an insulating layer disposed on the first electrode and the second electrode. The insulating layer may include a first recess disposed on the first electrode and a second recess disposed on the second electrode.

The semiconductor element may further a first pad disposed in the first recess and electrically connected to the first electrode; and a second pad disposed in the second recess and electrically connected to the second electrode.

The second pad may not overlap the first electrode in a thickness direction of the semiconductor structure.

The first pad may be partially disposed on the first electrode to overlap the first electrode in the thickness direction of the semiconductor structure.

A sensor according to an embodiment of the present invention includes a housing; a first semiconductor element disposed in the housing and configured to emit ultraviolet light; and a second semiconductor element disposed in the housing. The second semiconductor element includes a substrate; and a semiconductor structure disposed on the substrate. The semiconductor structure includes a first conductive semiconductor layer; a second conductive semiconductor layer; and a light absorbing layer disposed between the first conductive semiconductor layer and the second conductive semiconductor layer. The light absorbing layer has a ratio of a maximum outer length of an upper surface to a maximum area of the upper surface, the ratio ranging from 1.25 to 1.5.

A semiconductor element according to an embodiment includes a substrate; first and second conductive semiconductor layers disposed on the substrate; a light absorbing layer disposed between the first conductive semiconductor layer and the second conductive semiconductor layer; a first electrode disposed in at least one recess that exposes the first conductive semiconductor layer by passing through the second conductive semiconductor layer and the light absorbing layer, and connected to the first conductive semiconductor layer; and a second electrode connected to the second conductive semiconductor layer. The light absorbing layer may have a planar shape surrounding the at least one recess.

For example, a ratio of a first planar area of the light absorbing layer to an entire planar area of the first conductive semiconductor layer may be greater than 64.87%.

For example, the at least one recess may include a plurality of recesses, and the plurality of recesses may be spaced apart from in a symmetrical shape and in a planar fashion.

For example, the semiconductor element may operate in a photovoltaic mode.

For example, the at least one recess may have a circular, elliptical or polygonal planar shape.

For example, the semiconductor structure including the first conductive semiconductor layer, the second conductive semiconductor layer, and the light absorbing layer may include a central area between portions of the light absorbing layer in the recess positioned inside an edge of the semiconductor structure; and a peripheral area in which the light absorbing layer is disposed, the peripheral area more protruding than the central area and having a greater planar shape than the central area.

For example, the first electrode may be disposed on all surfaces or a portion of the first conductive semiconductor layer exposed in the at least one recess.

For example, the semiconductor element may further include a first insulating layer disposed between the first electrode and side portions of the light absorbing layer and the second conductive semiconductor layer exposed in the recess; a first cover metal layer disposed to surround the first electrode; and a second cover metal layer disposed to surround the second electrode.

For example, the semiconductor element may further include a first pad connected to the first electrode through the first cover metal layer; a second pad connected to the second electrode through the second cover metal layer; and a second insulating layer disposed between the first pad and the second cover metal layer, configured to open upper portions of the first and second cover metal layers to which the first pad and the second pad are to be connected, and disposed on all surfaces of the semiconductor structure.

For example, the exposed first cover metal layer that is not covered by the second insulating layer may have a circular planar shape and may have a diameter of 10 μm to 150 μm in a planar fashion.

For example, the first conductive semiconductor layer may be of an n type, and the second conductive semiconductor layer may be of a p type.

### Advantageous Effects of the Invention

According to the embodiments, it is possible to implement a semiconductor element in the form of a flip chip.

Also, it is possible to manufacture a semiconductor element with a decreased dark current.

Also, it is possible to manufacture a semiconductor element with improved reaction sensitivity.

The semiconductor element according to the embodiment has a higher photocurrent with respect to the same chip area than that of a comparative example, and thus the semiconductor element may have good sensing sensitivity and provide a high degree of freedom of the design.

Various advantageous merits and effects of the present invention are not limited to the above-descriptions and will be easily understood while embodiments of the present invention are described in detail.

### DESCRIPTION OF THE DRAWINGS

FIG. 1 is a top view of a semiconductor element according to an embodiment.

FIG. 2 is a sectional view taken along A-A′ of FIG. 1.

FIG. 3 is a view showing distances between a semiconductor element and first and second electrodes according to an embodiment.

FIG. 4 is a view showing a plan view of B-B′ of FIG. 3.

FIG. 5 is a view showing semiconductor elements having light absorbing layers with the same area but various peripheral lengths.

FIG. 6 is a diagram showing dark currents of the semiconductor elements of FIG. 5.

FIG. 7 is a view showing semiconductor elements having various perimeter-to-area ratios of the light absorbing layer.

FIG. 8 is a diagram showing dark currents of the semiconductor elements of FIG. 7.

FIG. 9 is a diagram showing gains of the semiconductor elements of FIG. 7.

FIG. 10 is a diagram showing a photocurrent with respect to the area of the light absorbing layer of the semiconductor element.

FIG. 11 is a diagram showing various distances between the light absorbing layer and a first electrode.

FIG. 12 is a diagram showing dark currents corresponding to the various distances of FIG. 11.

FIG. 13 is a diagram showing various distances between the light absorbing layer and a second electrode.

FIG. 14 is a diagram showing dark currents corresponding to the various distances of FIG. 13.

FIGS. 15A to 15F are diagrams showing a method of manufacturing a semiconductor element according to an embodiment.

FIG. 16 is a diagram showing a semiconductor element according to another embodiment.

FIG. 17 shows a plan view of a semiconductor element according to an embodiment.

FIG. 18 shows a sectional view of the semiconductor element taken along line I-I′ shown in FIG. 17.

FIG. 19 shows a plan view of a semiconductor element according to another embodiment.

FIG. 20 shows a plan view of a semiconductor element according to still another embodiment.

FIG. 21 shows a sectional view of a semiconductor element having a flip-chip bonding structure according to an embodiment.

FIGS. 22A to 22F are processing sectional views illustrating a method of manufacturing a semiconductor element according to an embodiment.

FIG. 23 shows a plan view of a semiconductor element according to a comparative example.

FIG. 24 shows a sectional view of the semiconductor element taken along line II-II′ shown in FIG. 23 according to the comparative example.

FIG. 25 shows a plan view of a semiconductor element according to another comparative example.

FIG. 26 shows a plan view of a semiconductor element according to still another comparative example.

FIG. 27 is a graph showing a change in photocurrent by wavelength in the semiconductor element according to the comparative example.

FIG. 28 is a graph showing a peak response ratio according to an activation ratio.

FIG. 29 is a diagram showing another sensor according to an embodiment.

FIG. 30 is a conceptual view showing an electronic product according to an embodiment.

### MODE OF THE INVENTION

The present invention may be variously modified and have several example embodiments, and specific embodiments will be shown in the accompanying drawings and be described in detail. It should be understood, however, that there is no intent to limit the invention to the particular forms disclosed, but on the contrary, the invention is to cover all modifications, equivalents, and alternatives falling within the spirit and scope of the invention.

Although the terms “first,” “second,” etc., may be used herein to describe various elements, these elements should not be limited by these terms. These terms are used only to distinguish one element from another. For example, a first element may be called a second element, and a second element may also be called a first element without departing from the scope of the present invention. The term “and/or” means any one or a combination of a plurality of related items.

It should be understood that when an element is referred to as being “connected” or “coupled” to another element, the element can be directly connected or coupled to the other element or intervening elements may be present. Conversely, when an element is referred to as being “directly connected” or “directly coupled” to another element, there are no intervening elements present.

The terminology used herein is for the purpose of describing particular embodiments only and is not intended to be limiting the invention. As used herein, the singular forms “a,” “an,” and “the” are intended to include the plural forms as well, unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or a combination thereof.

Unless otherwise defined, all terms (including technical and scientific terms) used herein have the same meaning as commonly understood by those skilled in the art. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

A semiconductor element may include various kinds of electronic elements such as a light emitting element, a light receiving element, and the like, and the light emitting element and the light receiving element may each include a first conductive semiconductor layer, an active layer (a light absorbing layer), and a second conductive semiconductor layer.

The light emitting element emits light by recombination of electrons and holes, and the wavelength of the light is determined by an energy band gap inherent to material. Therefore, the emitted light may vary depending on the composition of the material.

The above-described light emitting element may be configured as a light emitting element package and be used as a light source of a lighting system. For example, the light emitting element may be used as a light source of an image display device or a light source of a lighting device.

When the light emitting element is used as a backlight unit of an image display device, the light emitting element may be used as an edge-type backlight unit or a direct-type backlight unit. When the light emitting element is used as a light source of a lighting device, the light emitting element may be used as a lamp or a bulb. Alternatively, the light emitting element may be used as a light source of a mobile terminal.

The light emitting element includes a light emitting diode or a laser diode.

The light emitting diode may include a first conductive semiconductor layer, a second conductive semiconductor layer, and a light absorbing layer, which have the above-described structures. The light emitting diode and the laser diode may be identical to each other in that the two diodes use an electro-luminescence phenomenon in which light is emitted when electric current flows after a p-type second conductive semiconductor layer and an n-type first conductive semiconductor layer are bounded to each other. However, the light emitting diode and the laser diode may have differences with respect to the directionality and phase of the emitted light. That is, the laser diode uses stimulated emission and constructive interference phenomena so that light with a specific single wavelength (monochromatic beam) may be emitted at the same phase and in the same direction. Due to these characteristics, the laser diode may be used for an optical communication device, a medical device, a semiconductor processing device, or the like.

The semiconductor element according to this embodiment may be a light receiving element.

The light receiving element may include a thermal element that converts photon energy into thermal energy, a photoelectric element that converts photon energy into electrical energy, or the like. In particular, the photoelectric element may have a light absorbing layer for absorbing light energy above an energy band gap of a light absorbing layer material to generate electrons and holes. Then, an electric current may be generated with the movement of the electrons and holes due to an electric field applied from the outside of the photoelectric element.

The light receiving element may include, for example, a photodetector, which is a kind of transducer that detects light and converts intensity of the light into an electric signal. The photodetector may include, but is not limited to, a photocell (silicon and selenium), a photoconductive element (cadmium sulfide and cadmium selenide), a photodiode (e.g., a PD having a peak wavelength in a visible blind spectral region or a true blind spectral region), a phototransistor, a photomultiplier, a photoelectric tube (vacuum and gas filling), an infra-red (IR) detector, or the like.

Generally, a semiconductor element such as the photodetector may be produced using a direct band gap semiconductor having good photo-conversion efficiency. Alternatively, the photodetector may have various structures. As the most common structure, the photodetector may include a pin-type photodetector using a p-n junction, a Schottky-type photodetector using a Schottky junction, a metal-semiconductor-metal (MSM)-type photodetector, or the like.

Like the light emitting element, the light receiving element, such as a photodiode, may include a first conductive semiconductor layer, a second conductive semiconductor layer, and a light absorbing layer (or an active layer), which have the above-described structure and may be composed of a p-n junction or a pin structure. The photodiode operates when a reverse bias or a zero bias is applied. When light is incident on the photodiode, electrons and holes are generated such that electric current flows. In this case, the magnitude of electric current may be approximately proportional to intensity of the light incident on the photodiode.

A photocell or a solar cell, which is a kind of photodiode, may convert light into electric current. Like the light emitting element, the solar cell may include a first conductive semiconductor layer having a first conductive type, a second conductive semiconductor layer having a second conductive type, and a light absorbing layer disposed between the first conductive semiconductor layer and the second conductive semiconductor layer, which have the above-described structure.

Also, the solar cell may be used as a rectifier of an electronic circuit through rectification characteristics of a general diode using a p-n junction and may be applied to an oscillation circuit or the like of a microwave circuit.

Also, the above-described semiconductor element is not necessarily implemented only with semiconductors. In some cases, the semiconductor element may additionally include a metal material. For example, a semiconductor element such as the light receiving element may be implemented using at least one of Ag, Al, Au, In, Ga, N, Zn, Se, P, and As and may be implemented using an intrinsic semiconductor material or a semiconductor material doped with a p-type dopant or an n-type dopant.

The semiconductor element according to this embodiment may be an avalanche photodiode (APD). The APD may further include an amplification layer with a high electric field and between the first conductive semiconductor layer and the second conductive semiconductor layer. As electrons or holes moved to the amplification layer collide with nearby atoms due to a high electric field, new electrons and holes may be generated. By repeating this process, electric current may be amplified. Accordingly, the APD may react sensitively even to a small amount of light, and thus may be used for a high sensitivity sensor or for long distance communication.

Hereinafter, example embodiments of the present invention will be described in detail with reference to the accompanying drawings. In the figures, the same reference numerals are used to denote the same elements throughout the drawings and redundant descriptions thereof will be omitted.

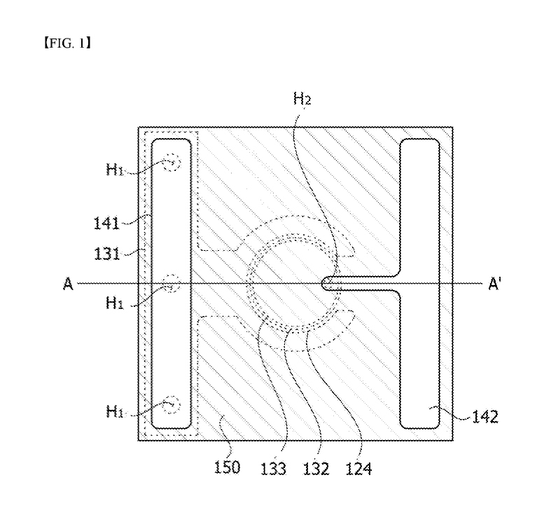

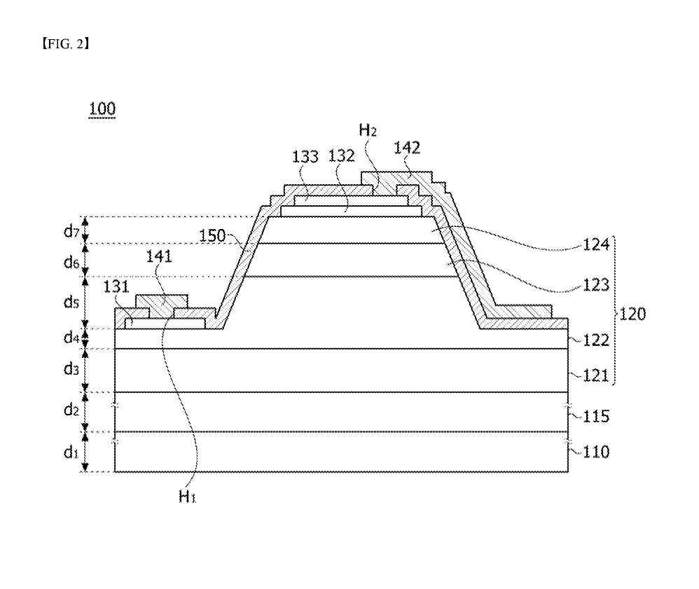

FIG. 1 is a top view of a semiconductor element according to an embodiment, and FIG. 2 is a sectional view taken along A-A′ of FIG. 1.

Referring to FIG. 2 first, a semiconductor element 100 according to an embodiment may include a substrate 110, a buffer layer 115, a semiconductor structure 120, a first electrode 131, a second electrode 132, a cover layer 133, a first pad 141, a second pad 142, and an insulating layer 150.

The substrate 110 may be a transparent, conductive, or insulating substrate 110. For example, the substrate 110 may contain at least one of sapphire (Al₂O₃), SiC, Si, GaAs, GaN, ZnO, GaP, InP, Ge, and Ga₂O₃.

Through the substrate 110, light may be provided to the semiconductor structure 120. The substrate 110 may have a thickness d1 of 250 μm to 450 μm. However, there is no limitation on the thickness.

The buffer layer 115 may be disposed on the substrate 110. The buffer layer 115 may mitigate deformation caused by a lattice constant difference between the substrate 110 and the semiconductor structure 120.

The buffer layer 115 may prevent diffusion of a material contained in the substrate 110. To this end, the buffer layer 115 may have a thickness d2 of 3 μm to 5 μm, but the present invention is not limited thereto. Here, the thickness is identical to a thickness direction of the semiconductor structure 120.

The buffer layer 115 may contain one material selected from among AlN, AlAs, GaN, AlGaN, and SiC or include a bi-layer structure thereof. In some cases, the buffer layer 115 may be omitted. In some cases, a superlattice structure may be disposed on the buffer layer 115.

The semiconductor structure 120 may be disposed on the substrate 110 (or the buffer layer 115). The semiconductor structure 120 may include a filter layer 121, a first conductive semiconductor layer 122, a light absorbing layer 123, and a second conductive semiconductor layer 124.

Among light received through the substrate 110 and the buffer layer 115, the filter layer 121 may transmit light of a predetermined wavelength or less and may filter out light of greater than the predetermined wavelength. The filter layer 121 may filter out UV-C light with a center wavelength of 280 nm. For example, the filter layer 121 may filter out light in a certain wavelength band of a predetermined ratio with respect to the center wavelength of the UV-C light. With this configuration, the filter layer 121 may filter out UV-C light directed onto fungi and transmit light in a fluorescence wavelength band generated from the fungi.

The filter layer 121 may contain Al. Also, the filter layer 121 may have various Al compositions depending on the wavelength band of the absorbed light. For example, the filter layer 121 of the semiconductor element 100 according to an embodiment may have an Al composition of 15% and absorb light with a wavelength of 320 nm or less. With this configuration, light with a wavelength of greater than 320 nm may pass through the filter layer 121.

That is, the filter layer 121 may have a band gap to filter out light with a wavelength smaller than a desired wavelength in order to prevent the light from being absorbed by the light absorbing layer 123.

However, the filter layer 121 does not filter out only the light with the wavelength, but may have a wavelength band to variably filter out depending on the wavelength of the light absorbed by the light absorbing layer 123. By way of example, the filter layer 121 may adjust a thickness and composition according to an absorption wavelength of the light absorbing layer 123. In this case, the filter layer 121 may transmit light in a wavelength band greater than the wavelength band of the light absorbing layer 123.

Also, the filter layer 121 may improve a growth condition for the first conductive semiconductor layer 122, which is an undoped layer and is disposed above, to mitigate lattice mismatch.

The filter layer 121 may have a thickness d3 of 0.45 μm to 0.55 μm. However, there is no limitation on the thickness.

The first conductive semiconductor layer 122 may be disposed on the filter layer 121. The first conductive semiconductor layer 122 may be doped with the aforementioned first dopant. That is, the first conductive semiconductor layer 122 may be an n-type semiconductor layer doped with an n-type dopant. The first dopant may be an n-type dopants such as Si, Ge, Sn, Se, and Te. That is, the first conductive semiconductor layer 122 may be an n-type semiconductor layer doped with an n-type dopant.

The first conductive semiconductor layer 122, which is a low resistance layer, may be a contact layer in contact with an electrode. Thus, up to a partial area of the first conductive semiconductor layer 122 may be mesa-etched. That is, the second conductive semiconductor layer 124, the light absorbing layer 123, and the partial area of the first conductive semiconductor layer 122 may be mesa-etched. Thus, a thickness to which the mesa etching is performed may be smaller than the total thickness d4 to d7 of the second conductive semiconductor layer 124, the light absorbing layer 123, and the first conductive semiconductor layer 122. For example, the thickness to which the mesa etching is performed may be equal to the sum of the thickness d7 of the second conductive semiconductor layer, the thickness d6 of the light absorbing layer 123, and the partial thickness d5 of the first conductive semiconductor layer 122.

Also, the first conductive semiconductor layer 122 may perform secondary filtering. By way of example, the first conductive semiconductor layer 122 may absorb light of 320 nm or less which is filtered out by the filter layer 121 and transmit light with a wavelength greater than 320 nm to the light absorbing layer 123 to supplement the filtering function of the filter layer 121.

Also, the first conductive semiconductor layer 122 may have a thickness d4+d5 of 0.9 μm to 1.1 μm, but the present invention is not limited thereto.

The light absorbing layer 123 may be an i-type semiconductor layer. That is, the light absorbing layer 123 may include an intrinsic semiconductor layer. Here, the intrinsic semiconductor layer may be an undoped semiconductor layer or an unintentionally doped semiconductor layer.

The unintentionally doped semiconductor layer may refer to a semiconductor layer which is not doped with dopants, for example, an n-type dopant such as a silicon (Si) atom during a process of growing the semiconductor layer and in which an N-vacancy has occurred. In this case, as the number of N-vacancies increases, the concentration of surplus electrons increases. Thus, it is possible to unintentionally obtain electrical characteristics similar to those in the case of doping with an n-type dopant in a manufacturing process. Up to a partial area of the light absorbing layer 123 may be doped with a dopant by diffusion.

The light absorbing layer 123 may absorb light incident onto the semiconductor element 100. That is, the light absorbing layer 123 may absorb light having energy greater than or equal to an energy band gap of a material of which the light absorbing layer 123 is formed and thus may generate carriers including electrons and holes. Electric current may flow through the semiconductor element 100 with the movement of the carriers.

That is, the light absorbing layer 123 may be in a totally depleted mode. Reverse bias may form a depletion region, and light absorbed through an absorbing region may expand in the depletion region. Also, the absorbed light may generate an electron-hole pair in the depletion region. Also, each carrier may obtain a sufficient amount and then drift an electric field to affect ionization. Through such a process, the carriers are drifted to a region to which a high electric field is applied. At a point called an avalanche region, the carrier generates an additional electron-hole pair through ionization shock, and the generated electron-hole pair provides a chain reaction. In detail, the moved carrier collides with nearby atoms to generate new carriers such as electrons and holes, and each of the generated carriers collides with nearby atoms to generate carriers. Thus, carrier multiplication may be performed.

Accordingly, the light absorbing layer 123 may have an avalanche function, which is a phenomenon in which electric current is amplified. Through such a configuration, the semiconductor element 100 according to an embodiment may amplify electric current through carrier amplification even when light with low energy is incident due to the light absorbing layer 123. In other words, since the light with low energy may be detected, it is possible to improve light receiving sensitivity.

Since the light absorbing layer 123 further contains Al, it is possible to improve the amplification effect. That is, the electric field in the light absorbing layer 123 may further increase due to the Al contained in the light absorbing layer 123.

For example, the light absorbing layer 123 may have the highest electric field. Therefore, the high electric field of the light absorbing layer 123 may be advantageous for carrier acceleration and may allow carriers and electric current to be effectively amplified.

The light absorbing layer 123 may have a thickness d6 of 500 nm to 2000 nm. For example, when the thickness of the light absorbing layer 123 is less than 500 μm, a space capable of amplifying the carriers is so small that the improvement of the amplification may be insignificant. When the thickness d6 of the light absorbing layer 123 is greater than 2000 nm, the electric field decreases such that a negative (−) electric field may be formed. However, the present invention is not limited thereto.

The second conductive semiconductor layer 124 may be disposed on the light absorbing layer 123. The second conductive semiconductor layer 124 may be doped with a second dopant. Here, the second dopant may be a p-type dopant such as Mg, Zn, Ca, Sr, and Ba. That is, the second conductive semiconductor layer 124 may be a p-type semiconductor layer doped with a p-type dopant. The second conductive semiconductor layer 124 may have a thickness d7 of 300 nm to 400 nm, but the present invention is not limited thereto.

The semiconductor structure 120 according to an embodiment of the present invention may have a structure in which an n-i-n diode and an n-i-p diode are bonded to each other by the first conductive semiconductor layer 122.

Also, generally, a high electric field may be formed by the i-type semiconductor layer having a higher resistance than the n-type semiconductor layer and the p-type semiconductor layer. Also, a higher electric field may be formed by the p-type semiconductor layer having a higher resistance than the n-type semiconductor layer. Accordingly, it may be advantageous to perform carrier amplification in a region adjacent to the p-type semiconductor layer, which forms a higher electric field.

The first electrode 131 may be disposed on the first conductive semiconductor layer 122. The first electrode 131 may contain, but is not limited to, at least one of indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—Ga ZnO (AGZO), In—Ga ZnO (IGZO), ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, and Hf.

The second electrode 132 may be disposed on the second conductive semiconductor layer 124. The second electrode 132 may be electrically connected to the second conductive semiconductor layer 124. The second electrode may be formed of the same material as that of the first electrode 131. For example, the second electrode 132 may contain, but is not limited to, at least one of ITO, IZO, IZTO, IAZO, IGZO, IGTO, AZO, ATO, GZO, IZON, AGZO, IGZO, ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, and Hf.

The cover layer 133 may be partially disposed on the second electrode 132. The cover layer 133 may enhance spreading of electric current provided to the second electrode 132. With this configuration, the cover layer 133 may enhance reaction sensitivity. The cover layer 133 may be formed of a material selected from among Ti, Ru, Rh, Ir, Mg, Zn, Al, In, Ta, Pd, Co, Ni, Si, Ge, Ag, Au, and selective alloys thereof.

The first pad 141 may be disposed on the first electrode 131. The first pad 141 may be disposed on a partial area of the first electrode 131. The first pad 141 may be electrically connected to the first electrode 131 to electrically connect the semiconductor element 100 to an external circuit.

The first pad 141 may be formed of a material selected from among Ti, Ru, Rh, Ir, Mg, Zn, Al, In, Ta, Pd, Co, Ni, Si, Ge, Ag, Au, and selective alloys thereof.

The second pad 142 may be disposed on the second electrode 132 (or the cover layer 133). The second pad 142 may be disposed in a partial area of the second electrode 132 (or the cover layer 133). The second pad 142 may be electrically connected to the second electrode 132 to electrically connect the semiconductor element 100 to an external circuit.

Like the first pad 141, the second pad 142 may be formed of a material selected from among Ti, Ru, Rh, Ir, Mg, Zn, Al, In, Ta, Pd, Co, Ni, Si, Ge, Ag, Au, and selective alloys thereof.

The insulating layer 150 may cover the first conductive semiconductor layer 122, the light absorbing layer 123, and the second conductive semiconductor layer 124. Also, the insulating layer 150 may partially cover the first electrode 131. With this configuration, the insulating layer 150 may form a first recess H1 on the first electrode 131. The first electrode 131 and the first pad 141 may be electrically connected to each other through the first recess H1.

Referring to FIG. 1, the first pad 141 may be disposed in a partial area of the first electrode 131, and the first electrode 131 may be electrically connected to the first pad 141 through the first recess H1. The first recess H1 may include a plurality of first recesses, and there is no limitation on the number.

Also, the insulating layer 150 may cover a portion of the second electrode 132 (or the cover layer 133). With this configuration, the insulating layer 150 may form a second recess H2 on the second electrode 132 (or the cover layer 133). The second electrode 132 and the second pad 142 may be electrically connected to each other through the second recess H2.

The insulating layer 150 may prevent the first electrode 131 from being electrically in direct contact with the second conductive semiconductor layer 124 or the second electrode 132. That is, the insulating layer 150 may isolate the first electrode 131 from the second electrode 132.

The insulating layer 150 may be formed of at least one material selected from the group consisting of SiO₂, SiₓO_{y}, Si₃N₄, SiₓN_{y}, SiOₓN_{y}, Al₂O₃, TiO₂, and AlN, but is not limited thereto.

In detail, the first electrode 131 may be shaped to surround the first conductive semiconductor layer 122, the light absorbing layer 123, and the second conductive semiconductor layer 124 that are mesa-etched. For example, the first electrode 131 may be formed in the shape of tongs to surround the first conductive semiconductor layer 122 that is mesa-etched.

Also, the first pad 141 disposed on the first electrode 131 and the second pad 142 disposed on the second electrode 132 over the semiconductor element 100 may be placed to face each other with respect to the first conductive semiconductor layer 122, the light absorbing layer 123, and the second conductive semiconductor layer 124 disposed at the center of the semiconductor element 100. That is, the first pad 141 may be spaced apart from and be electrically disconnected from the second pad 142.

Also, the first pad 141 may overlap the first electrode 131 in the thickness direction of the semiconductor structure 120, and the second pad 142 may partially overlap the second electrode 132 in the thickness direction of the semiconductor structure 120.

Also, the second pad 142 does not overlap the first electrode 131 in the thickness direction of the semiconductor structure 120. For example, the first electrode 131 may have the shape of tongs, and both ends of the tongs may be spaced apart from each other. Also, the second pad 142 may extend to a space between the two ends of the tongs. With this configuration, the second pad 142 and the first electrode 131 may be electrically separated from each other.

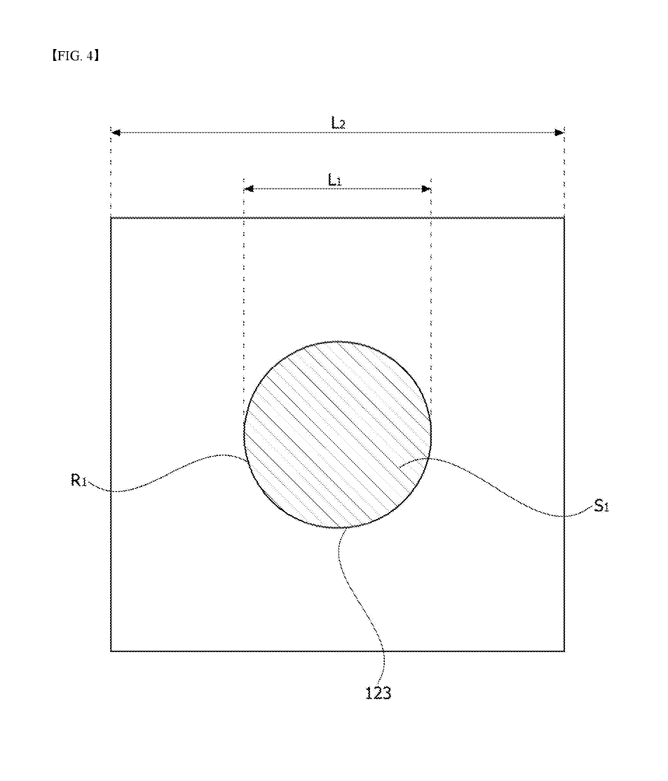

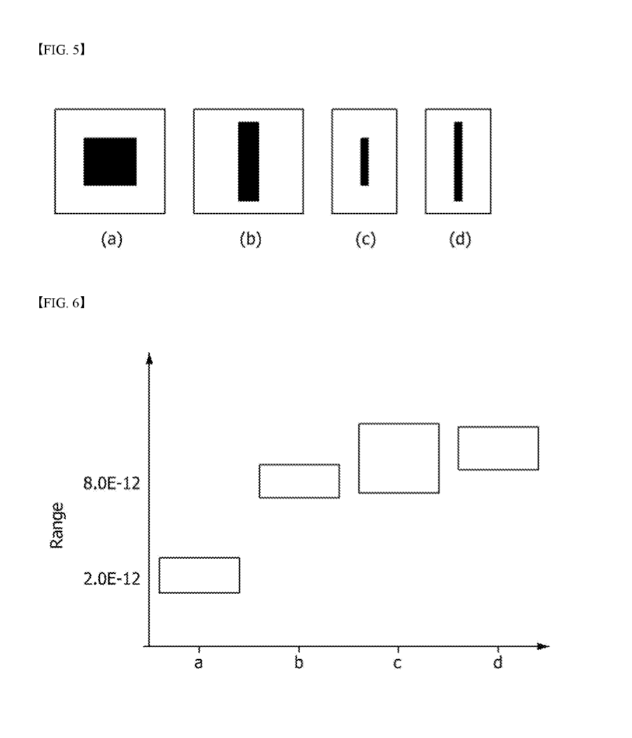

Also, the first conductive semiconductor layer 122, the light absorbing layer 123, and the second conductive semiconductor layer 124 that are mesa-etched may be circular. The configuration may be formed by mesa-etching. This will be described in detail below with reference to FIGS. 5 and 6.

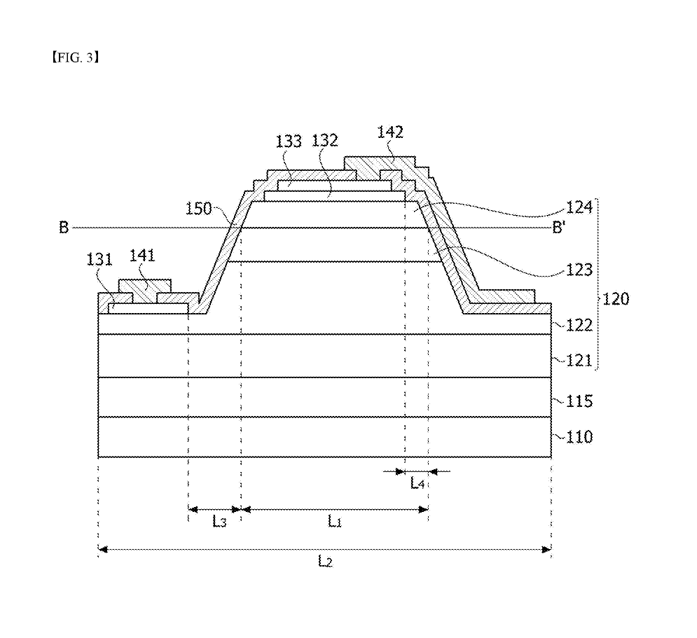

FIG. 3 is a view showing distances between a semiconductor element and first and second electrodes according to an embodiment, and FIG. 4 is a view showing a plan view of B-B′ of FIG. 3.

Referring to FIGS. 3 and 4, an upper surface of the light absorbing layer 123 may be circular, as described above. The upper surface of the light absorbing layer 123 may have a diameter L1 of 280 μm to 320 μm. Also, the following description assumes that the upper surface of the light absorbing layer 123 has a maximum outer length of R1 and a maximum area of S1.

Also, the semiconductor element 100 may have an entire width L2 of 900 μm to 1000 μm. Here, the width may be vertical to the thickness direction of the semiconductor structure 120.

The semiconductor element 100 may be one of a plurality of semiconductor elements 100 formed on a wafer, and the entire width of the semiconductor element 100 is not limited thereto and may have various values. For example, the configuration may be applied even to a semiconductor element 100 having a size scaling in units of several microns or millimeters.

Also, the first electrode 131 and the upper surface of the light absorbing layer 123 may have a minimum distance L3 of 5 μm or greater. However, the present invention is not limited thereto, but the minimum distance L3 between the first electrode 131 and the upper surface of the light absorbing layer 123 has a limitation in being difficult to design in the semiconductor process.

The second electrode 132 may be partially disposed on an upper surface of the second conductive semiconductor layer 124. However, the present invention is not limited thereto, and the second electrode 132 may have the same area as the upper surface of the second conductive semiconductor layer 124. For example, when the second electrode 132 is disposed on the second conductive semiconductor layer 124 and mesa etching is performed on the second electrode 132, a lower surface of the second electrode 132 may be coplanar with the upper surface of the second conductive semiconductor layer 124. With this configuration, electric current per unit area due to the second electrode 132 may increase, and thus it is possible to improve a gain. Here, the gain may be a ratio of an electric current (or voltage) when a predetermined reverse bias is applied by the semiconductor element 100 to an electric current (or voltage) when a zero bias is applied by the semiconductor element 100.

Also, in the semiconductor element 100, the second electrode 132 and the upper surface of the light absorbing layer 123 may have a minimum distance L4. For example, when mesa etching is performed at 90 degrees or less, a minimum distance L4 may be formed between the second electrode 132 and the upper surface of the light absorbing layer 123 by the angle of the mesa etching. Thus, the minimum distance L4 between the second electrode 132 and the light absorbing layer 123 may be several nanometers.

FIG. 5 is a view showing semiconductor elements having light absorbing layers with the same area but various peripheral lengths, and FIG. 6 is a diagram showing dark currents of the semiconductor elements of FIG. 5.

Referring to FIG. 5, FIGS. 5A to 5D show semiconductor elements having light absorbing layers having upper surfaces with the same maximum area but different maximum outer lengths.

FIG. 5A relates to a semiconductor element having a light absorbing layer having a square upper surface. The maximum area of the upper surface of the light absorbing layer is 200*200 μm², and the maximum outer perimeter of the upper surface of the light absorbing layer is 782.8 μm (the maximum outer perimeter refers to a maximum outer length).

Also, FIG. 5B relates to a semiconductor element having a light absorbing layer having a rectangular upper surface. The maximum area of the upper surface of the light absorbing layer is 100*400 μm², and the maximum outer perimeter of the upper surface of the light absorbing layer is 982.8 μm.

Also, FIG. 5C relates to a semiconductor element having a light absorbing layer having a rectangular upper surface. The rectangular upper surface of the light absorbing layer in FIG. 5C has either a width or a height being larger and the other being smaller than that in FIG. 5B. In FIG. 5C, the maximum area of the upper surface of the light absorbing layer is 66.67*600 μm², and the maximum outer perimeter of the upper surface of the light absorbing layer is 1316.2 μm.

Also, FIG. 5D relates to a semiconductor element having a light absorbing layer having a rectangular upper surface. The rectangular upper surface of the light absorbing layer in FIG. 5D has either a width or a height being larger and the other being smaller than that in FIG. 5C. In FIG. 5D, the maximum area of the upper surface of the light absorbing layer is 50*800 μm², and the maximum outer perimeter of the upper surface of the light absorbing layer is 1682.8 μm.

Referring to FIG. 6, it can be seen that dark current decreases as the maximum outer length of the upper surface of the light absorbing layer in the semiconductor element decreases while dark current increases as the maximum outer length of the upper surface of the light absorbing layer increases (in FIG. 6, range denotes a degree of dark current).

Thus, it can be seen that the dark current decreases by minimizing the maximum outer length of the upper surface of the light absorbing layer while the maximum area of the upper surface of the light absorbing layer is constant. Thus, the upper surface of the light absorbing layer may be formed in a circular shape in order to minimize the maximum outer length while maintaining the maximum area.

In this case, the maximum outer perimeter of the upper surface of the light absorbing layer is minimized. Thus, the dark current may decrease, and finally an avalanche gain may increase. Accordingly, the semiconductor element may have improved reaction sensitivity.

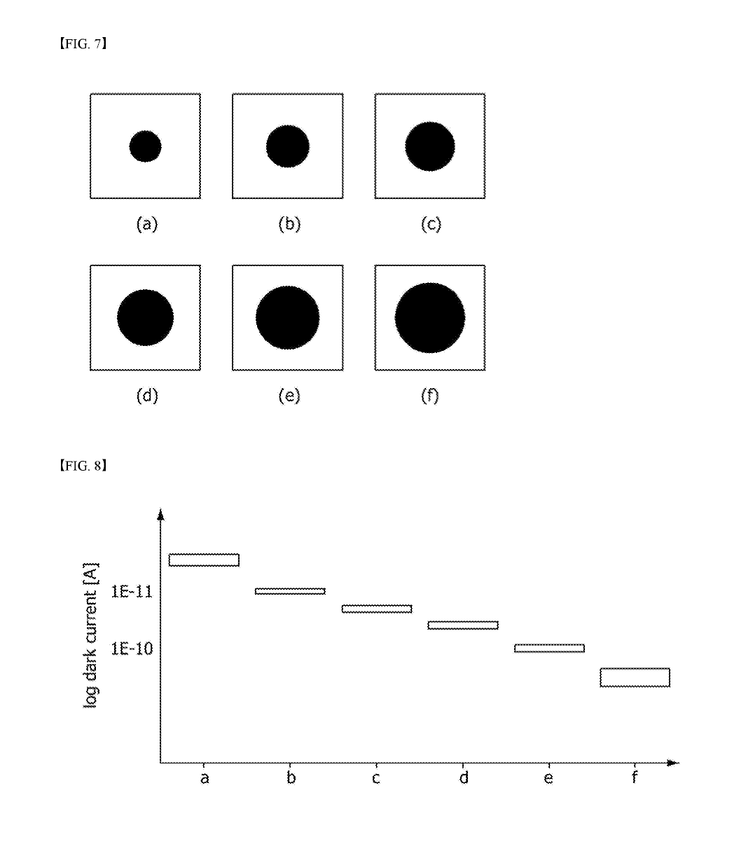

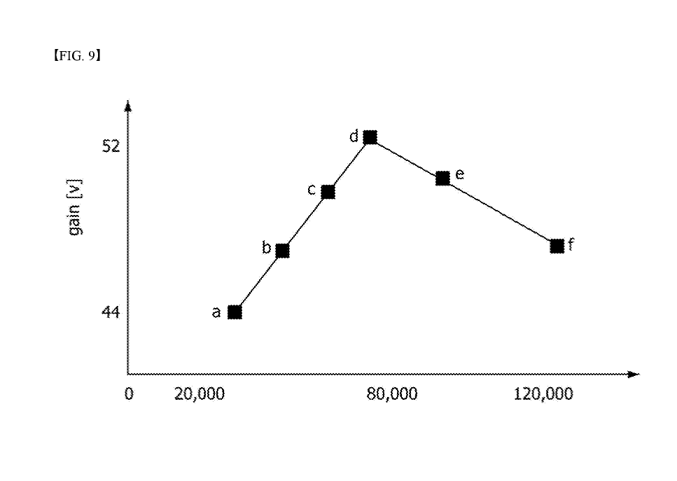

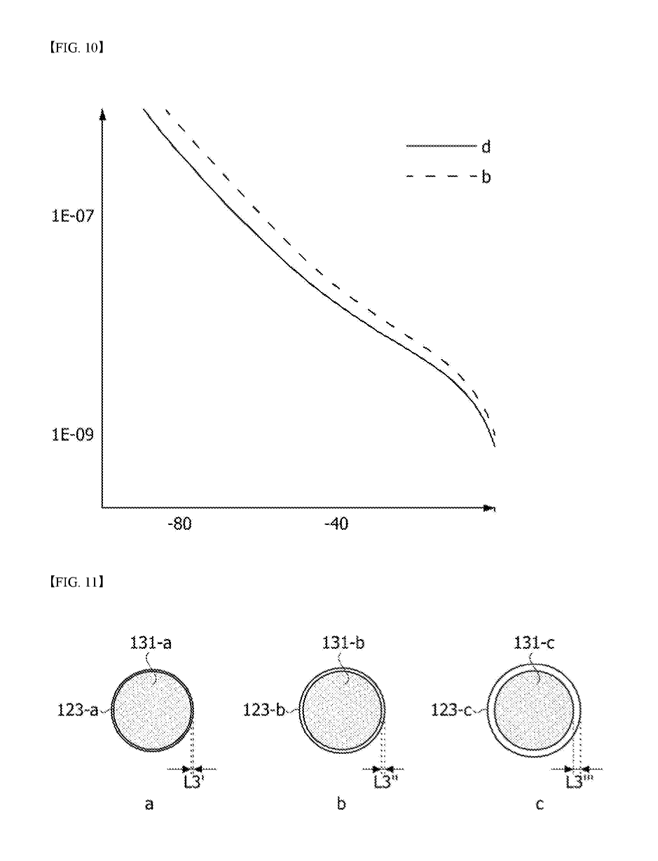

FIG. 7 is a view showing semiconductor elements having various perimeter-to-area ratios of the light absorbing layer, FIG. 8 is a diagram showing dark currents of the semiconductor elements of FIG. 7, FIG. 9 is a diagram showing gains of the semiconductor elements of FIG. 7, and FIG. 10 is a diagram showing a photocurrent with respect to the area of the light absorbing layer of the semiconductor element.

Referring to FIG. 7, the upper surfaces of the light absorbing layers may be all circular and have different maximum outer lengths (perimeters) with respect to maximum areas of the upper surfaces of the light absorbing layers.

FIGS. 7A to 7F are diagrams showing that the upper surfaces of the light absorbing layers in the semiconductor elements have the ratios of the maximum outer lengths to the maximum areas being 4%, 2%, 1.43%, 1.33%, 1.25%, and 1%, respectively. Here, the ratio of the maximum outer length to the maximum area of the upper surface of the light absorbing layer refers to (maximum outer length)/(maximum area of upper surface of light absorbing layer)*100. That is, the ratio of the maximum outer length to the maximum area of the upper surface of the light absorbing layer has length versus area as a variable. Referring to FIGS. 7A to 7F, although the upper surface of the light absorbing layer is circular, a photocurrent and a dark current may simultaneously increase as the area of the upper surface of the light absorbing layer increases. This is because as the area of the light absorbing layer increases, electron-hole generation and avalanche amplification increase and a dark current is also amplified.

Referring to FIG. 8 first, as the ratio of the maximum outer perimeter to the area of the upper surface of the light absorbing layer in the semiconductor element increases (from FIG. 7A to FIG. 7F), the dark current decreases in the semiconductor element.

Referring to FIG. 10, it can be seen that a photocurrent due to absorbed light increases as the area of the upper surface of the light absorbing layer in the semiconductor element increases (FIG. 10 shows that a photocurrent in FIG. 7D is greater than that in FIG. 7B, an x axis indicates an applied voltage, and a y axis indicates a photocurrent).

Accordingly, when the upper surface of the light absorbing layer is circular, it is possible to minimize the maximum outer perimeter, and thus it is possible to minimize a dark current caused by the maximum outer perimeter. However, a dark current and a photocurrent may be changed according to a ratio of the maximum outer perimeter of the upper surface of the light absorbing layer to the maximum area of the upper surface of the light absorbing layer. Therefore, there is a need to adjust a gain of the semiconductor element changed by the dark current and the photocurrent.

FIG. 9 illustrates gains of the semiconductor elements shown in FIGS. 7A to 7F. Accordingly, it can be seen that the gains when the ratios of the maximum outer lengths to the maximum areas of the upper surfaces of the light absorbing layers in the semiconductor elements are 1.43%, 1.33%, and 1.25% are more enhanced than the gains when the perimeter-to-area ratios of the upper surfaces of the light absorbing layers in the semiconductor elements are 4%, 2%, and 1%. Here, the x axis denotes the area of the upper surface of the light absorbing layer, and the y axis denotes the gain of the semiconductor element.

In detail, it can be seen that as the maximum area of the upper surface of the light absorbing layer in the semiconductor element increases, both of the dark current and the photocurrent increase, but have different increase rates, and thus the gain of the semiconductor element changes according to the rates.

Also, as the area of the upper surface of the light absorbing layer increases, the dark current and the photocurrent increase, but the photocurrent may have a drastically decreasing increase rate compared to the dark current. For example, the increase rate of the photocurrent may be saturated in a predetermined region. For this reason, the gain may decrease again, focusing on the semiconductor element shown in FIG. 7D. Thus, it can be seen that when the ratio of the maximum outer perimeter to the maximum area of the upper surface of the light absorbing layer ranges from 35% to 40%, the gain of the semiconductor element, which is 50 or greater, includes the maximum peak.

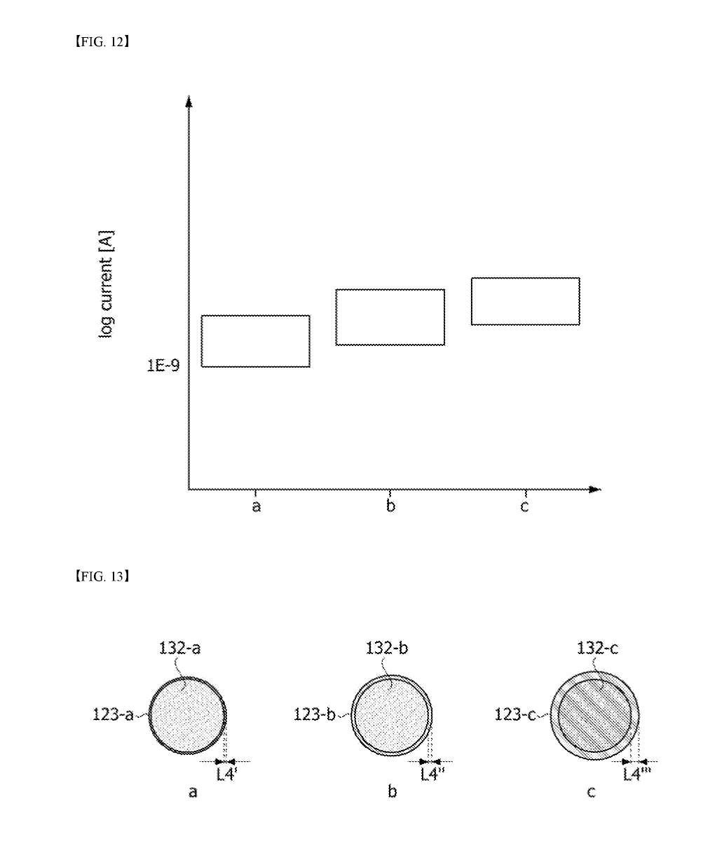

FIG. 11 is a diagram showing various distances between the light absorbing layer and a first electrode, and FIG. 12 is a diagram showing dark currents corresponding to the various distances of FIG. 11.

FIG. 11 shows semiconductor elements having various minimum distances between the first electrode and the upper surface of the light absorbing layer.

FIG. 11A shows a case in which the minimum distance L3′ between the first electrode and the upper surface of the light absorbing layer is 5 μm, FIG. 11B shows a case in which the minimum distance L3″ between the first electrode and the upper surface of the light absorbing layer is 10 μm, and FIG. 11C shows a case in which the minimum distance L3′″ between the first electrode and the upper surface of the light absorbing layer is 20 μm.

Referring to FIG. 12, it can be seen that dark currents of the semiconductor elements shown in FIGS. 11A to 11C increase as the minimum distance between the first electrode and the upper surface of the light absorbing layer decreases. Also, the minimum distance between the first electrode and the upper surface of the light absorbing layer may be 5 μm or greater in the manufacturing process. Thus, when the first electrode is disposed on the first conductive semiconductor layer mesa-etched up to a partial region, the dark current of the semiconductor element may be decreased by placing the first electrode as close to the mesa-etched region as possible.

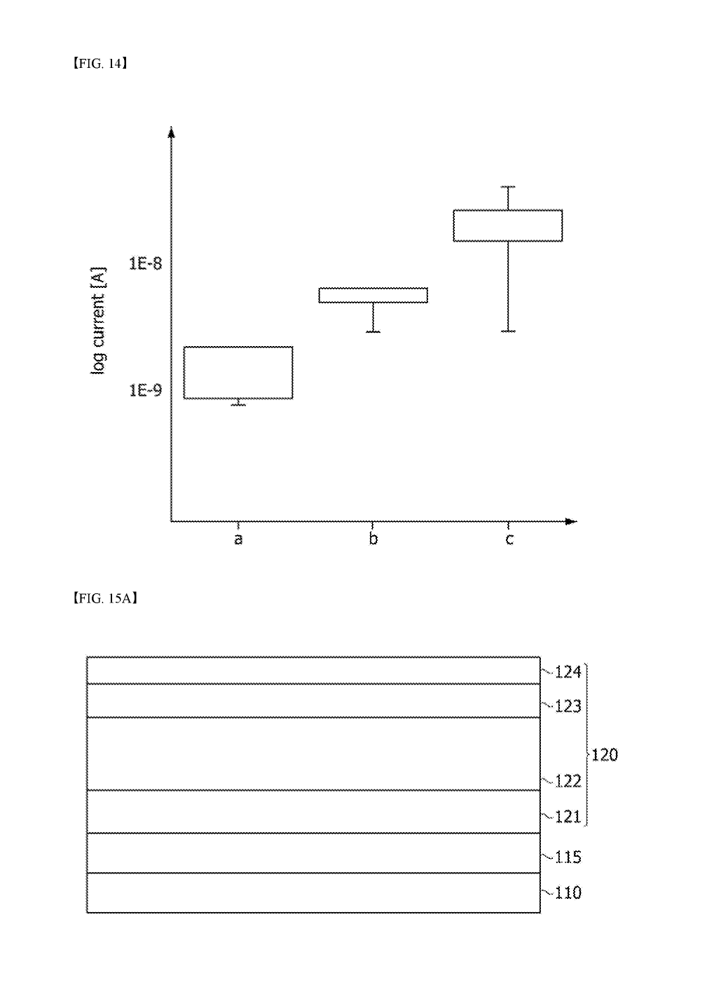

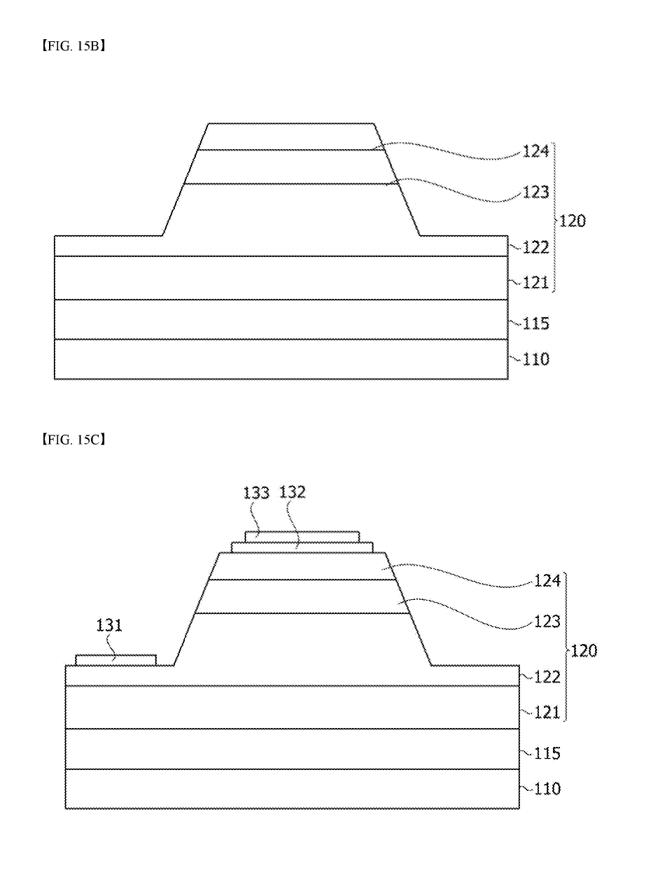

FIG. 13 is a diagram showing various distances between the light absorbing layer and a second electrode, and FIG. 14 is a diagram showing dark currents corresponding to the various distances of FIG. 13.

FIG. 13A shows a case in which the minimum distance L4′ between the second electrode and the upper surface of the light absorbing layer is 5 μm, FIG. 13B shows a case in which the minimum distance L4″ between the second electrode and the upper surface of the light absorbing layer is 10 μm, and FIG. 13C shows a case in which the minimum distance L4′″ between the second electrode and the upper surface of the light absorbing layer is 20 μm.

Referring to FIG. 14, it can be seen that dark currents of the semiconductor elements shown in FIGS. 13A to 13C increase as the minimum distance between the second electrode and the upper surface of the light absorbing layer decreases. Also, as described above, the minimum distance between the second electrode and the upper surface of the light absorbing layer may be set to various values according to the mesa-etching. Thus, when the second electrode has the same area as the upper surface of the second conductive semiconductor layer, the second electrode may be placed as close to the upper surface of the light absorbing layer as possible, and thus the dark current may be minimized. Accordingly, it is possible to enhance the gain of the semiconductor element.

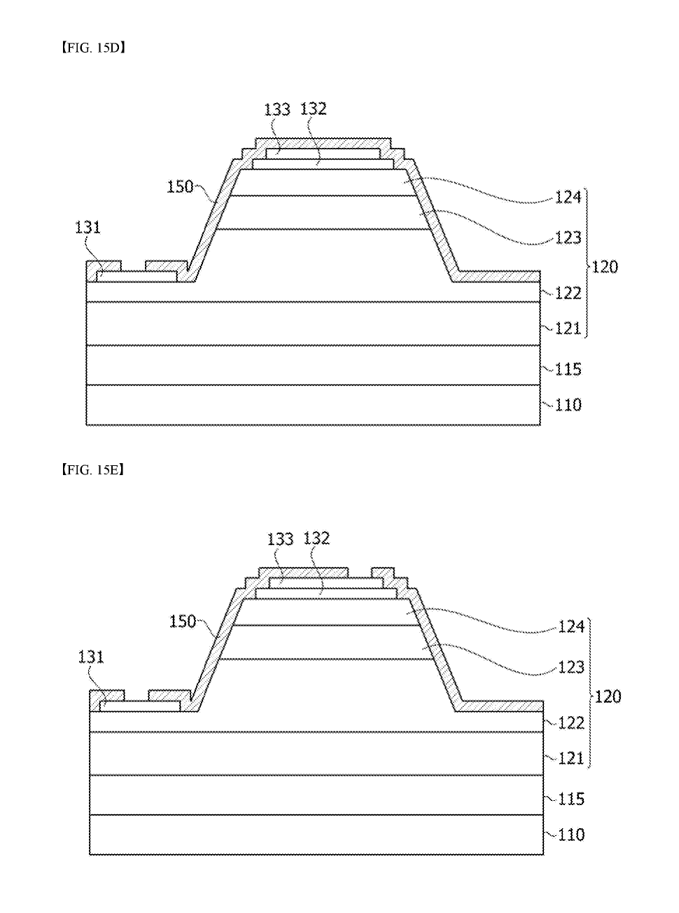

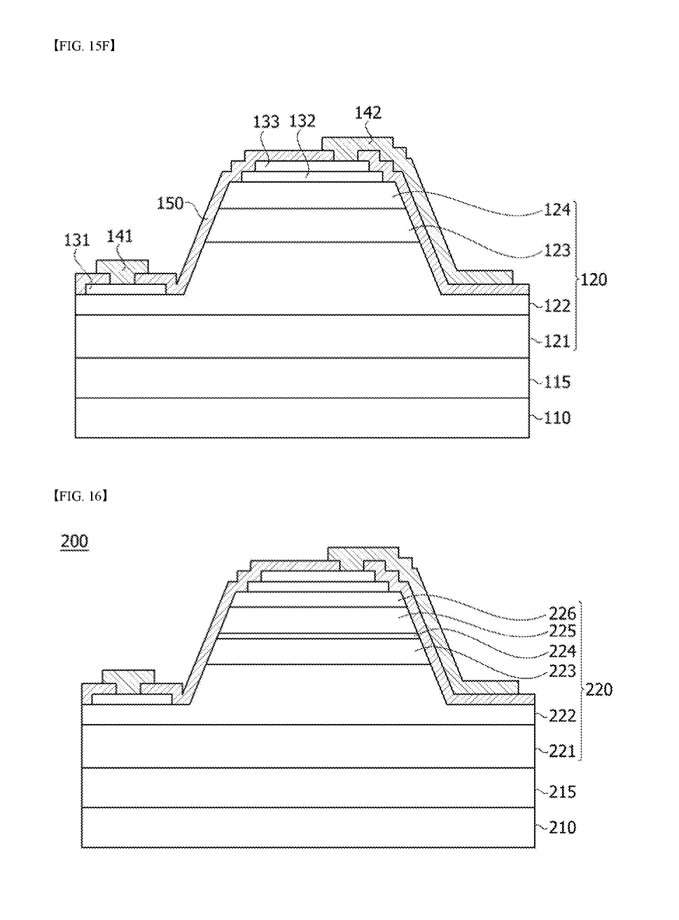

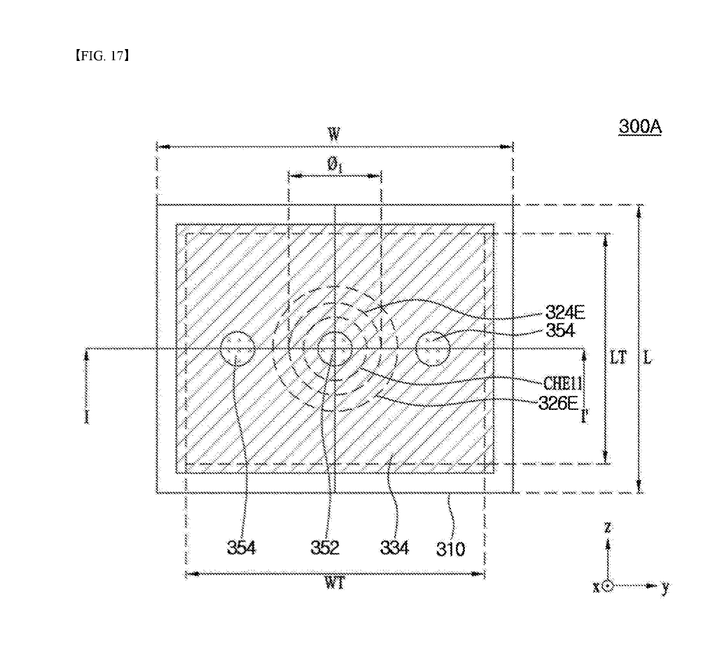

FIGS. 15A to 15F are diagrams showing a method of manufacturing a semiconductor element according to an embodiment.

Referring to FIG. 15A, a substrate 110, a buffer layer 115, and a semiconductor structure 120 may be formed. A filter layer 121, a first conductive semiconductor layer 122, a light absorbing layer 123, and a second conductive semiconductor layer 124 may be sequentially formed on the semiconductor structure 120.

The substrate 110, which transmits light injected into a lower portion of the semiconductor element, may be formed of a material selected from among sapphire (Al₂O₃), SiC, GaAs, GaN, ZnO, Si, GaP, InP, and Ge, but is not limited thereto. Also, the buffer layer 115 may be formed on the substrate 110 to mitigate a lattice mismatch between the substrate 110 and the semiconductor structure 120 provided on the substrate 110.

In addition, the semiconductor structure 120 may be formed using a metal organic chemical vapor deposition (MOCVD), chemical vapor deposition (CVD), plasma-enhanced chemical vapor deposition (PECVD), molecular-beam epitaxy (MBE), hydride vapor phase epitaxy (HVPE), sputtering, or the like.

Referring to FIG. 15B, up to a partial area of the first conductive semiconductor layer 122 may be mesa-etched. The mesa etching may be performed to a thickness that is greater than the total thickness of the second conductive semiconductor layer 124 and the light absorbing layer 123 and smaller than the total thickness of the first conductive semiconductor layer 122, the light absorbing layer 123, and the second conductive semiconductor layer 124.

Referring to FIG. 15C, a first electrode 131 may be disposed on a partial area of the first conductive semiconductor layer 122, and a second electrode 132 may be disposed on a partial area of the second conductive semiconductor layer 124. However, as described above, after the second electrode 132 is formed on the second conductive semiconductor layer 124, the mesa etching may be performed, and the first electrode 131 may be formed on the first conductive semiconductor layer 122.

Also, a cover layer 133 may be formed on the second electrode 132. As described above, the cover layer 133 may be formed of a metal material selected from among Ti, Ru, Rh, Ir, Mg, Zn, Al, In, Ta, Pd, Co, Ni, Si, Ge, Ag, Au, and selective alloys thereof.

Referring to FIG. 15D, an insulating layer 150 may be formed on the semiconductor structure 120, the first electrode 131, the second electrode 132, and the cover layer 133. The insulating layer 150 may be partially formed on the first electrode 131 to form a first recess. Also, the insulating layer 150 may be partially formed on the cover layer 133 to form a second recess.

Referring to FIG. 15E, a first pad 141 may be formed on the first recess, which is formed on the first electrode 131, to partially cover the insulating layer 150. The first pad 141 may be electrically connected to the first electrode 131 and may contain a metal material.

A second pad 142 may be formed on the second recess, which is formed on the second electrode 132, to partially cover the insulating layer 150. The second pad 142 may be electrically connected to the second electrode 132 and may contain a metal material like the first pad 141. Also, the second pad 142 may extend in a direction facing the first pad 141 with respect to the second conductive semiconductor layer 124.

FIG. 16 is a diagram showing a semiconductor element according to another embodiment.

Referring to FIG. 16, a semiconductor element 200 may include a substrate 210, a semiconductor structure 220, a first electrode, and a second electrode. Also, a buffer layer 215 may be further disposed between the substrate 210 and the semiconductor structure 220.

The substrate 210 may be a transparent, conductive, or insulating substrate. For example, the substrate 210 may contain at least one of sapphire (Al₂O₃), SiC, Si, GaAs, GaN, ZnO, GaP, InP, Ge, and Ga₂O₃.

The buffer layer 215 may be disposed on the substrate 210. The buffer layer 215 may mitigate deformation caused due to a lattice constant difference between the substrate 210 and a first conductive first semiconductor layer 222.

Also, the buffer layer 215 may prevent diffusion of the material contained in the substrate. To this end, the buffer layer 215 may have a thickness of 300 nm to 3000 nm, but the present invention is not limited thereto. Here, the thickness is in a thickness direction of the semiconductor structure 220.

The buffer layer 215 may contain one material selected from among AlN, AlAs, GaN, AlGaN, and SiC or include a bi-layer structure thereof. In some cases, the buffer layer 215 may be omitted.

The semiconductor structure 220 may be disposed on the substrate 210 (or the buffer layer 215). The semiconductor structure 220 may include a filter layer 221, the first conductive first semiconductor layer 222, a light absorbing layer 223, a first conductive second semiconductor layer 224, an amplification layer 225, and a second conductive semiconductor layer 226.

Each of the layers (the filter layer 221, the first conductive first semiconductor layer 222, the light absorbing layer 223, the first conductive second semiconductor layer 224, the amplification layer 225, and the second conductive semiconductor layer 226) may be implemented with at least one of Group III-V and Group II-VI compound semiconductor materials. The semiconductor structure 220 may be formed of a semiconductor material having an empirical formula of, for example, InₓAl_{y}Ga_{1-x-y}N (0≤x≤1, 0≤y≤1, 0≤x+y≤1). For example, the semiconductor structure 220 may contain GaN.

The filter layer 221 may be disposed at the bottom of the semiconductor structure. The filter layer 221 may be an undoped layer, which is doped with no dopants.

Among light received through the substrate and the buffer layer, the filter layer 221 may transmit light of a predetermined wavelength or less and filter out light of greater than the predetermined wavelength. The filter layer 221 may filter out UV-C light with a center wavelength of 280 nm. For example, the filter layer 221 may filter out light in a certain wavelength band of a predetermined ratio with respect to the center wavelength of the UV-C light. With this configuration, the filter layer 221 may filter out UV-C light directed onto fungi and transmit light in a fluorescence wavelength band generated from the fungi.

The filter layer 221 may contain Al. Also, the filter layer 221 may have various Al compositions depending on the wavelength band of the absorbed light. For example, the filter layer 221 of the semiconductor element according to an embodiment may have an Al composition of 15% and absorb light with a wavelength of 320 nm or less. With this configuration, light with a wavelength of greater than 320 nm may pass through the filter layer 221.

That is, the filter layer 221 may have a band gap to filter out light with a wavelength smaller than a desired wavelength in order to prevent the light from being absorbed by the light absorbing layer.

However, the filter layer 221 does not filter out only the light with the wavelength, but may have a wavelength band to variably filter out depending on the wavelength of the light absorbed by the light absorbing layer. By way of example, the filter layer 221 may adjust a thickness and composition according to an absorption wavelength of the light absorbing layer. In this case, the filter layer 221 may transmit light in a wavelength band greater than the wavelength band of the light absorbing layer.

The first-prime conductive semiconductor 222 layer may be disposed on the substrate 210 (or the buffer layer 215). The first conductive first semiconductor layer 222 may be doped with a first dopant. Here, the first dopant may be an n-type dopant such as Si, Ge, Sn, Se, and Te. That is, the first conductive first semiconductor layer 222 may be an n-type semiconductor layer doped with an n-type dopant. Also, the first conductive first semiconductor layer 222 may have a thickness of 500 nm to 2000 nm, but the present invention is not limited thereto.

Also, the first conductive first semiconductor layer 222 may contain Al. Also, the first conductive first semiconductor layer 222 may have various Al compositions depending on the wavelength band of the absorbed light. The first conductive first semiconductor layer 222 may have a band gap to filter out light with a wavelength greater than a desired wavelength in order to prevent the light from being absorbed by the light absorbing layer 223.

For example, when the semiconductor element 200 according to an embodiment absorbs light of 320 nm or less, the first conductive first semiconductor layer 222 may have an Al composition of 15%. However, the Al composition of the first conductive first semiconductor layer 222 is not limited thereto, and the first conductive first semiconductor layer 222 may have various Al compositions depending on the wavelength band of the absorbed light.

The light absorbing layer 223 may be disposed on the first conductive first semiconductor layer 222. The light absorbing layer 223 may have a thickness of 100 nm to 200 nm, but the present invention is not limited thereto.

The light absorbing layer 223 may be an i-type semiconductor layer. That is, the light absorbing layer 223 may include an intrinsic semiconductor layer. Here, the intrinsic semiconductor layer may be an undoped semiconductor layer or an unintentionally doped semiconductor layer.

The unintentionally doped semiconductor layer may refer to a semiconductor layer which is not doped with dopants, for example, an n-type dopant such as a silicon (Si) atom during a process of growing the semiconductor layer and in which an N-vacancy has occurred. In this case, as the number of N-vacancies increases, the concentration of surplus electrons increases. Thus, it is possible to unintentionally obtain electrical characteristics similar to those in the case of doping with an n-type dopant in a manufacturing process. Up to a partial area of the light absorbing layer 223 may be doped with dopants by diffusion.

The light absorbing layer 223 may absorb light incident onto the semiconductor element 200. That is, the light absorbing layer 223 may absorb light having energy greater than or equal to an energy band gap of a material of which the light absorbing layer 223 is formed and thus may generate carriers including electrons and holes. Electric current may flow through the semiconductor element 200 with the movement of the carriers.

For example, the light absorbing layer 223 may have different materials depending on wavelengths of fluorescence unique to microorganisms such as fungi. The first conductive second semiconductor layer 224 may be disposed on the light absorbing layer 223. The first conductive second semiconductor layer 224 may be doped with the aforementioned first dopant. That is, the first conductive second semiconductor layer 224 may be an n-type semiconductor layer doped with an n-type dopant. The first conductive second semiconductor layer 224 may have a thickness of 20 nm to 60 nm, but the present invention is not limited thereto.

Also, as described above, the light absorbing layer 223 may have a ratio of the maximum outer length of an upper surface to the maximum area of the upper surface ranging from 35% to 40%. With this configuration, the semiconductor element 200 may have a decreased dark current and an improved gain.

The first conductive second semiconductor layer 224 may be disposed between the light absorbing layer 223 and the amplification layer 225. The first conductive second semiconductor layer 224 may make an electric field between the light absorbing layer 223 and the amplification layer 225 different. In particular, the first conductive second semiconductor layer 224 may allow a higher electric field to be concentrated in the amplification layer 225, as shown in FIG. 2. Accordingly, carrier multiplication may be performed focusing on the amplification layer 225 having the highest electric field.

The amplification layer 225 may be disposed on the first conductive second semiconductor layer 224. Like the light absorbing layer 223, the amplification layer 225 may be an i-type semiconductor layer. Also, the amplification layer 225 may further contain Al. That is, the amplification layer 225 may be composed of a compound of Al and a material contained in the light absorbing layer 223. For example, the amplification layer 225 may have a single-layer structure including AlGaN.

The amplification layer 225 may multiply carriers generated in the light absorbing layer 223. That is, the amplification layer 225 may have an avalanche function. Avalanche is an electric current amplification phenomenon in which when a reverse bias is applied, the semiconductor element 200 absorbs light to generate carriers and the generated carriers consecutively generate other carriers so that electric current is amplified.

The carriers moved to the amplification layer 225 collide with nearby atoms to generate new carriers such as electrons and holes, and each of the generated carriers collides with nearby atoms to generate carriers. Thus, carrier multiplication may be performed. The electric current of the semiconductor element 200 may increase due to the carrier multiplication. That is, the semiconductor element 200 may amplify electric current through the carrier amplification even when light with low energy is incident due to the amplification layer 225. In other words, since the light with low energy may be detected, it is possible to improve light receiving sensitivity.

Since the amplification layer 225 further contains Al, it is possible to improve the amplification effect. That is, the electric field in the amplification layer 225 may further increase due to the Al contained in the amplification layer 225.

For example, the amplification layer 225 may have the highest electric field. Therefore, the high electric field of the amplification layer 225 may be advantageous for carrier acceleration and may allow carriers and electric current to be effectively amplified.

The amplification layer 225 may have a thickness of 50 nm to 100 nm. When the thickness of the amplification layer 225 is less than 50 nm, a space capable of amplifying the carriers is so small that the improvement of the amplification may be insignificant. When the thickness of the amplification layer 225 is greater than 100 nm, the electric field decreases such that a negative (−) electric field may be formed.

The second conductive semiconductor layer 226 may be disposed on the amplification layer 225. The second conductive semiconductor layer 226 may be doped with a second dopant. Here, the second dopant may be a p-type dopant such as Mg, Zn, Ca, Sr, and Ba. That is, the second conductive semiconductor layer 226 may be a p-type semiconductor layer doped with a p-type dopant. The second conductive semiconductor layer 226 may have a thickness of 300 nm to 400 nm, but the present invention is not limited thereto.

The first electrode, the second electrode, the insulating layer, the first pad, and the second pad may be applied in the same manner as described with reference to FIG. 2.

Semiconductor elements 300A to 100C according to embodiments will be described below using a Cartesian coordinate system (x, y, z), but the embodiments are not limited thereto. That is, it will be appreciated that the embodiments may be described using another coordinate system. In the figures, the x axis, the y axis, and the z axis are described as being orthogonal to each other, but the embodiments are not limited thereto. That is, the x axis, the y axis, and the z axis may cross each other without being orthogonal to each other.

Also, the semiconductor elements 300A, 200B, and 200C according to embodiments, which will be described below, refer to light receiving elements, but the embodiments are not limited thereto.

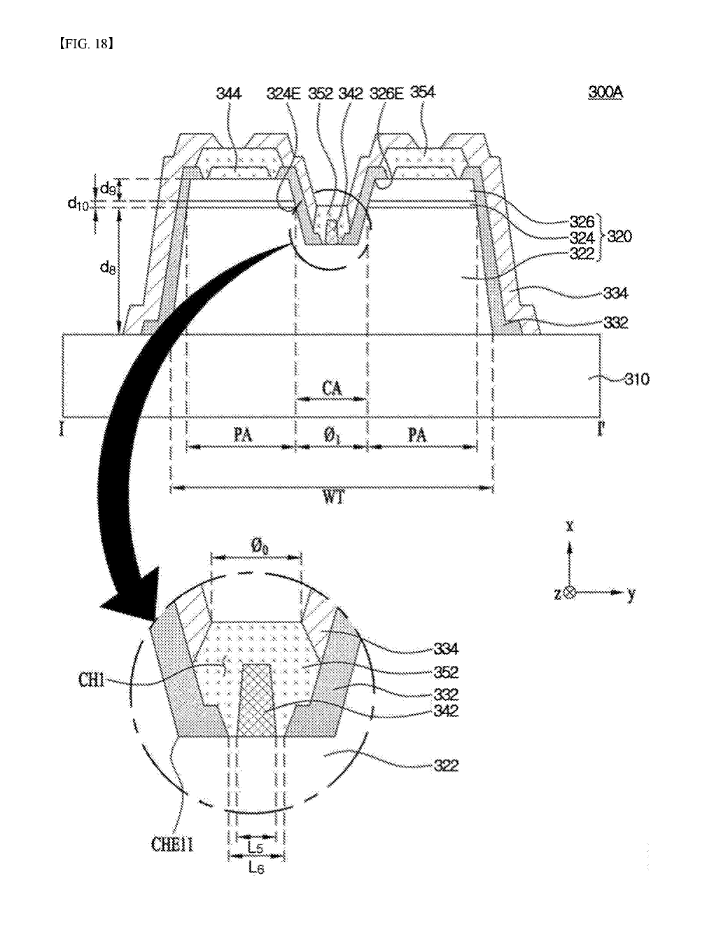

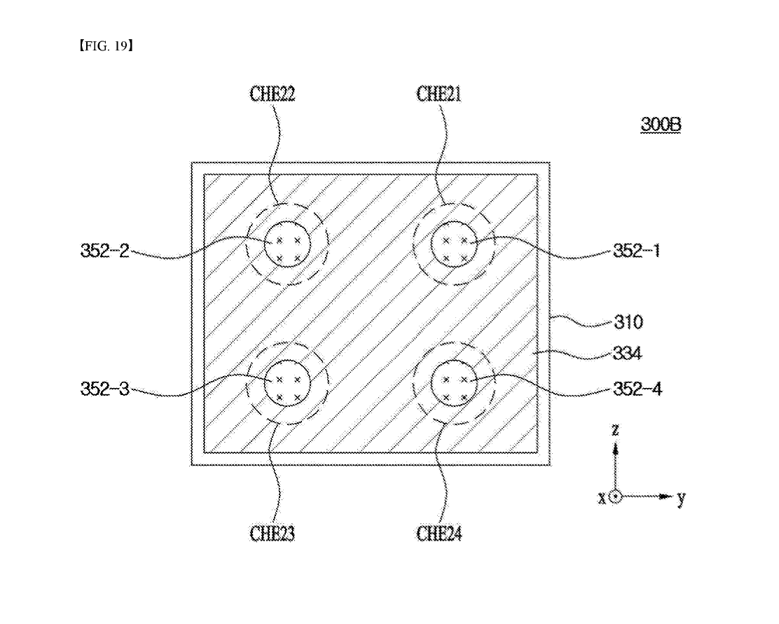

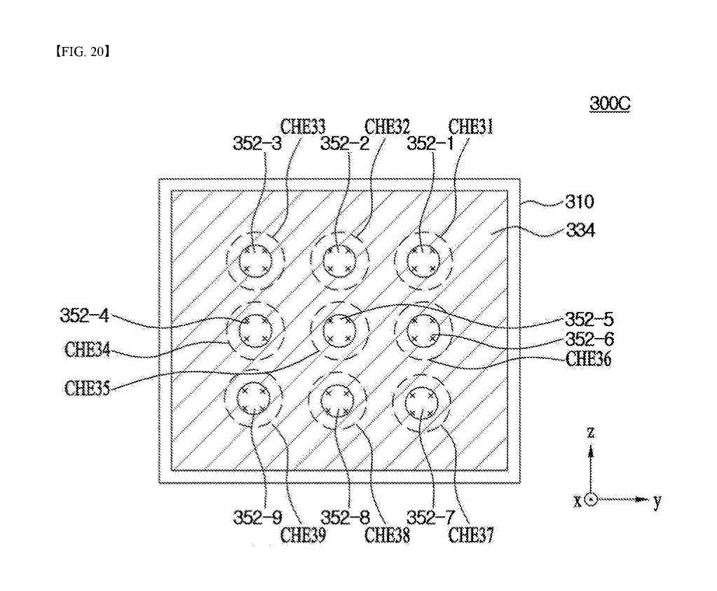

FIG. 17 shows a plan view of a semiconductor element 300A according to an embodiment, and FIG. 18 shows a sectional view of the semiconductor element 300A taken along line I-I′ shown in FIG. 17.

Referring to FIGS. 17 and 18, the light receiving element 300A according to an embodiment may include a substrate 310, a semiconductor structure 20, a first insulating layer 332, a second insulating layer 334, a first electrode 342, a second electrode 344, a first cover metal layer 352, and a second cover metal layer 354.

A semiconductor structure 320 is disposed on the substrate 310. For example, the semiconductor structure 320 may be formed on the (0001) plane of the sapphire substrate 310. The substrate 310 may contain a conductive material or a non-conductive material. For example, the substrate 310 may contain at least one of sapphire (Al₂O₃), GaN, SiC, ZnO, GaP, InP, Ga₂O₃, GaAs, and Si, but the embodiments are not limited to a specific material of the substrate 310.

Also, in order to improve a thermal expansion coefficient difference and a lattice mismatch between the substrate 310 and the semiconductor structure 320, a buffer layer (not shown) may be further disposed between a first conductive semiconductor layer 322 of the semiconductor structure 320 and the substrate 310. The buffer layer may contain at least one material selected from the group consisting of, for example, Al, In, N, and Ga, but the present invention is not limited thereto. Also, the buffer layer may have a single-layer structure or a multi-layer structure. For example, the buffer layer may be composed of AlN and have a thickness of 100 nm, but the embodiments are not limited thereto. As shown in FIG. 18, the buffer layer may be omitted.

The semiconductor structure 320 may include the first conductive semiconductor layer 322, a second conductive semiconductor layer 326, and a light absorbing layer (or an active layer) 324.

The first conductive semiconductor layer 322 and the second conductive semiconductor layer 326 may have different conductive types. For example, the first conductive semiconductor layer 322 may be a first conductive semiconductor layer doped with a first conductive dopant, and the second conductive semiconductor layer 326 may be a second conductive semiconductor layer doped with a second conductive dopant. The first conductive dopant may be an n-type dopant and may include, but is not limited to, Si, Ge, Sn, Se, and Te. Also, the second conductive dopant may be a p-type dopant and may include, but is not limited to, Mg, Zn, Ca, Sr, and Ba. According to another embodiment, the first conductive dopant may be a p-type dopant, and the second conductive dopant may be an n-type dopant.

The first conductive semiconductor layer 322 may be disposed on the substrate 310 and may have a first thickness D8 of 250 nm, but the embodiments are not limited thereto. The second conductive semiconductor layer 326 may have a thickness D9 of 30 nm, but the embodiments are not limited thereto.

The light absorbing layer 324 may be disposed between the first conductive semiconductor layer 322 and the second conductive semiconductor layer 326. For example, the light absorbing layer 324 may have a third thickness D10 of several tens of micrometers, but the embodiments are not limited to a specific value.

In addition, although not shown, by an amplification layer being further disposed between the second conductive semiconductor layer 326 and the light absorbing layer 324, a strong electric field is generated at a boundary between the light absorbing layer 324 and the amplification layer and at a portion of the amplification layer near the boundary. Also, carriers (e.g., electrons) being multiplied and avalanched in the amplification layer due to the strong electric field, it is possible to improve the gain of the semiconductor element 300A.

The first conductive semiconductor layer 322, the second conductive semiconductor layer 326, the light absorbing layer 324, and the amplification layer may each be formed of a semiconductor compound. For example, the first conductive semiconductor layer 322, the second conductive semiconductor layer 326, the light absorbing layer 324, and the amplification layer may each contain a nitride semiconductor and may be implemented with heavily doped GaN. For example, each of the first conductive semiconductor layer 322, the second conductive semiconductor layer 326, the light absorbing layer 324, and the amplification layer may contain a semiconductor material having an empirical formula of InₓAl_{y}Ga_{1-x-y}N (0≤x≤1, 0≤y≤1, 0≤x+y≤1) or may contain any one or more of InAlAs, GaN, InN, AlN, InGaN, AlGaN, InAlGaN, AlInN, AlGaAs, InGaAs, AlInGaAs, GaP, AlGaP, InGaP, AlInGaP, and InP.

For example, the first conductive semiconductor layer 322 may contain n-type AlGaN, the second conductive semiconductor layer 326 may contain p-type AlGaN, and the light absorbing layer 324 may include i-AlGaN.

Alternatively, the first conductive semiconductor layer 322 may contain n-type InP, the second conductive semiconductor layer 326 may contain p-type InP, and the light absorbing layer 324 may include undoped InGaAs.

A photon of light incident onto the light receiving element 300A generates an electron-hole pair in the light absorbing layer 324. The generated electrons and holes may be detected as electric current by moving in opposite directions due to an electric field across the light absorbing layer 324 and meeting the first electrode 342 and the second electrode 344, respectively. Although not shown, a negative terminal and a positive terminal of an ammeter (not shown) are connected to the first electrode 342 and the second electrode 344, respectively, to measure the electric current generated in the light receiving element 300A.

According to an embodiment, the entire light absorbing layer 324 may be a depletion region. The light absorbing layer 324 may absorb light in a deep ultraviolet wavelength band. For example, the light absorbing layer 324 may absorb light having a wavelength band of 280 nm or less. However, the embodiments are not limited to a specific wavelength band of light absorbed by the light absorbing layer 324. That is, a desired wavelength band of the absorbed light may be variously set.

Alternatively, the light absorbing layer 324 may include a PIN structure. The PIN structure may include a fifth n-type semiconductor layer (not shown), an intrinsic semiconductor layer (not shown), and a sixth p-type semiconductor layer (not shown). The intrinsic semiconductor layer may be disposed between the fifth n-type semiconductor layer and the sixth p-type semiconductor layer. The intrinsic semiconductor layer may be an undoped semiconductor layer or an unintentionally doped semiconductor layer. The unintentionally doped semiconductor layer may refer to a semiconductor layer which is not doped with dopants, for example, a n-type dopant such as a silicon (Si) atom during a process of growing the semiconductor layer and in which an N-vacancy has occurred. In this case, as the number of N-vacancies increases, the concentration of surplus electrons increases. Thus, it is possible to unintentionally obtain electrical characteristics similar to those in the case of doping with an n-type dopant in a manufacturing process. The fifth n-type semiconductor layer may contain a semiconductor material having an empirical formula of, for example, AlₓGa₍₁₋ₓ₎N (0≤x≤1). The sixth p-type semiconductor layer may contain a semiconductor material having an empirical formula of, for example, Al_{y}Ga_{(1-y)}N (0≤y≤1). The intrinsic semiconductor layer may contain a semiconductor material having an empirical formula of, for example, Al_{z}Ga_{(1-z)}N (0≤z≤1).

The semiconductor element 300A, which is a light receiving element, may be of a back illumination type in which photons are incident onto the substrate 310 and may be of a forward illumination type in which photons are incident onto the second conductive semiconductor layer 326.

When the semiconductor element 300A is of the forward illumination type and the sixth p-type semiconductor layer have the same energy band gap as that of the intrinsic semiconductor layer, carriers in the sixth p-type semiconductor layer are exited and absorbed, and thus it may be difficult to provide the carriers to the intrinsic semiconductor layer. Thus, when aluminum (Al) is added to the intrinsic semiconductor layer, the carriers may be further absorbed in the sixth p-type semiconductor layer. By increasing the energy band gap of the sixth p-type semiconductor layer to prevent this, the carriers may be prevented from being absorbed in the sixth p-type semiconductor layer. Accordingly, in order to increase the energy band gap of the sixth p-type semiconductor layer over the energy band gap of the intrinsic semiconductor layer, Al may be further added to the sixth p-type semiconductor layer. That is, the content of aluminum z contained in the intrinsic semiconductor layer may be greater than or equal to the content of aluminum y contained in the sixth p-type semiconductor layer. However, the energy band gaps of the sixth p-type semiconductor layer and the intrinsic semiconductor layer are not limited thereto. This is because when the thickness of the sixth p-type semiconductor layer is sufficiently thin, carriers may not be absorbed in the sixth p-type semiconductor layer.

For example, the fifth n-type semiconductor layer may contain GaN, and each of the sixth p-type semiconductor layer and the intrinsic semiconductor layer may contain a semiconductor material having an empirical formula of Al_{0.45}Ga_{0.55}N. Also, the sixth p-type semiconductor layer may be much thinner than the intrinsic semiconductor layer.

Also, depending on whether the semiconductor element 300A is of a back illumination type or of a forward illumination type, the size or thickness of the energy band gaps of the fifth n-type semiconductor layer, the intrinsic semiconductor layer, and the sixth p-type semiconductor layer may be determined. The embodiments are not limited to specific values of the relative size and thickness of the energy band gaps.

At least one of the fifth n-type semiconductor layer, the intrinsic semiconductor layer, and the sixth p-type semiconductor layer may be a superlattice (SL) layer (or a superjunction (SL) layer). The minimum thicknesses of the fifth n-type semiconductor layer, the intrinsic semiconductor layer, and the sixth p-type semiconductor layer may be 50 Å, 50 Å, and 10 Å, respectively, but the embodiments are not limited thereto.

Meanwhile, the first electrode 342 may be disposed on the first conductive semiconductor layer 322 in at least one recess (or contact hole) CH1 that exposes the first conductive semiconductor layer 322 by passing through the light absorbing layer 324 and the second conductive semiconductor layer 326, and may be electrically connected to the first conductive semiconductor layer 322.

According to an embodiment, as shown in FIG. 18, the first electrode 342 may be disposed in a portion of the first conductive semiconductor layer 322 exposed by the at least one recess CH1. In this case, a first width L5 of the first electrode 342 may be smaller than a second width L6 of the exposed first conductive semiconductor layer 322 in a second direction different from a first direction in which the substrate 310 is viewed from the light emitting structure 320. Here, the second direction may be orthogonal to the first direction. For example, the first direction may be an x-axis direction, and the second direction may be a y-axis direction.

According to another embodiment, unlike FIG. 18, the first electrode 342 may be disposed on all surfaces of the first conductive semiconductor layer 322 exposed by the at least one recess CH1. In this case, the first width L5 may be the same as the second width L6.

The first electrode 342 may have a single-layer structure or a multi-layer structure. For example, the first electrode 342 may include a first layer (not shown) and a second layer (not shown). The first layer may contain Ti and may be disposed on the first conductive semiconductor layer 322 exposed by the recess CH1. The second layer may contain Al and may be disposed on the first layer.

Referring to FIG. 17, at least one recess CHE11 is illustrated as having a circular planar shape, but the embodiments are not limited thereto. That is, according to another embodiment, the contact hole CHE11 may have an elliptical or polygonal planar shape. Here, CHE11 refers to an edge of the recess CH1.

When the recess CH11 has a circular planar shape, referring to FIGS. 17 and 18, a diameter ϕ0 of the exposed first cover metal layer 352 (or a diameter of the recess) that is not covered by the second insulating layer 334 when viewed from the top may range from 10 μm to 150 μm, but the embodiments are not limited thereto.

The second electrode 344 may be disposed on the second conductive semiconductor layer 326 and be electrically connected to the second conductive semiconductor layer 326. The second electrode 344 may have a single-layer structure or a multi-layer structure. For example, the second electrode 344 may include a first layer (not shown) and a second layer (not shown). The first layer may contain Ni and be disposed on the second conductive semiconductor layer 326, and the second layer may contain Au and be disposed on the first p-type layer.

Each of the first electrode 342 and the second electrode 344 shown in FIG. 18 may be formed of a metal, which is selected from among Ag, Ni, Ti, Al, Rh, Pd, Ir, Ru, Mg, Zn, Pt, Au, Hf, Cr, and selective combinations thereof.

When the second electrode 344 contains an ohmic contact material, a separate ohmic layer may be omitted as illustrated in FIG. 18, but the embodiments are not limited thereto. That is, according to another embodiment, when the second electrode 344 does not include an ohmic contact material, a separate ohmic layer (not shown) performing an ohmic function may be disposed between the second electrode 344 and the second conductive semiconductor layer 326, unlike the example illustrated in FIG. 18. The ohmic layer may be a transparent conductive oxide (TCO). For example, the ohmic layer may contain at least one of ITO, IZO, IZTO, IAZO, IGZO, IGTO, AZO, ATO, GZO, IZON, AGZO, IGZO, ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, and Hf, but is not limited thereto.

According to an embodiment, the light absorbing layer 324 may have a planar shape surrounding the at least one recess CH1.

Also, referring to FIG. 18, the semiconductor structure 320 may include a central area (CA) and a peripheral area (PA). The CA refers to an area between portions of the light absorbing layer 324 in the recess CH1 located at the center of the inside of an edge of the semiconductor structure 320, and the PA refers to an area in which the light absorbing layer 324 is disposed. According to an embodiment, the PA may have a cross-sectional shape more protruding than the CA.

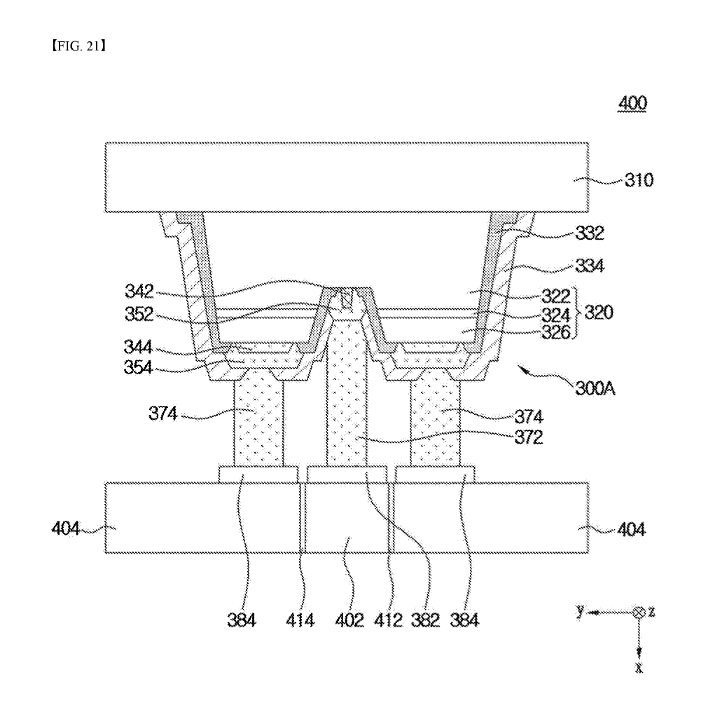

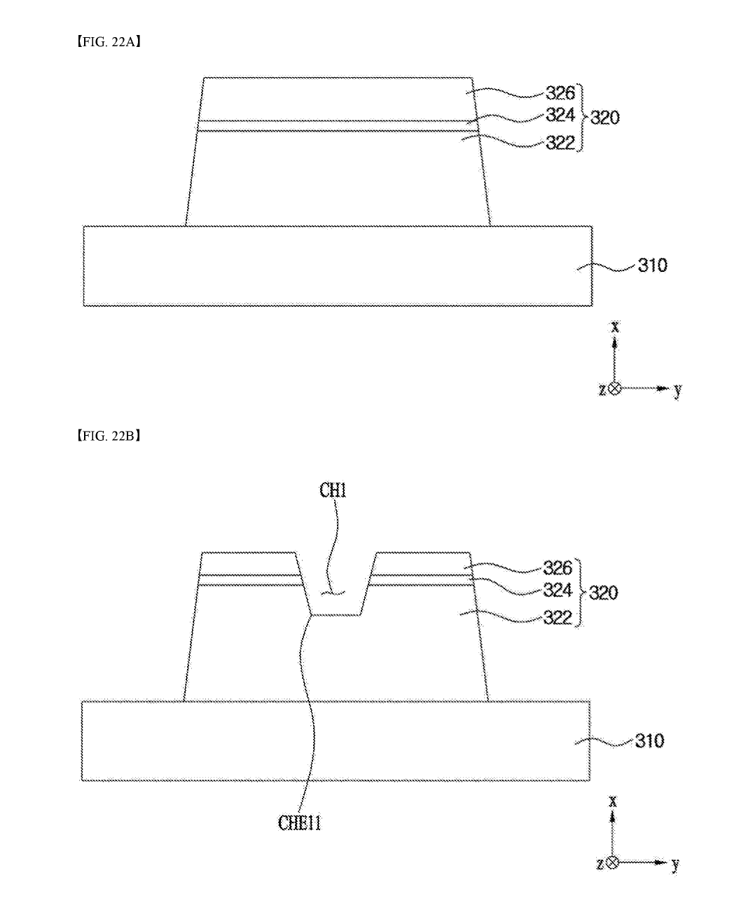

FIG. 19 shows a plan view of a semiconductor element 300B according to another embodiment, and FIG. 20 shows a plan view of a semiconductor element 300C according to still another embodiment. For convenience of description, the second electrode is omitted from FIGS. 19 and 20.

In FIGS. 17 and 18, the semiconductor element 300A includes only one recess CH1 or CHE11, but the embodiments are not limited thereto. That is, the at least one recess may include a plurality of recesses.

As illustrated in FIG. 18, the semiconductor element 300B may include four recesses CH21, CH22, CH23, and CH24. As CHE11 shown in FIG. 18 indicates the edge of the recess CH1, CHE21, CHE22, CHE23, and CHE24 shown in FIG. 19 indicate edges of fourth recesses CH21, CH22, CH23, and CH24, respectively.

Alternatively, as illustrated in FIG. 20, the semiconductor element 300C may include nine recesses CH31 to CH39. As CHE11 shown in FIG. 18 indicates the edge of the recess CH1, CHE31 to CH39 shown in FIG. 20 indicate edges of nine recesses CH31 to CH39, respectively.

The sectional shapes of the semiconductor elements 300B and 300C shown in FIGS. 19 and 20 are the same as that of the semiconductor element 300A shown in FIGS. 17 and 18 except for different locations and number of recesses CH21 to CH24 or CH31 to CH39. Accordingly, the sectional shapes of the semiconductor elements 300B and 300C shown in FIGS. 19 and 20 may be the same as that shown in FIG. 18. The semiconductor elements 300B and 300C shown in FIGS. 19 and 20 are the same as the semiconductor element 300A shown in FIGS. 17 and 18 except for different locations and number of recesses CH. Accordingly, the description of the semiconductor elements 300B and 300C shown in FIGS. 19 and 20 is replaced with the description of the semiconductor element 300A shown in FIGS. 17 and 18.

Also, when each of the semiconductor elements 300B and 300C includes a plurality of recesses, the plurality of recesses may be spaced apart from one another in a symmetrical shape and in a planar fashion as illustrated in FIGS. 19 and 20, but the embodiments are not limited thereto.

Referring to FIGS. 17 and 18 again, the first insulating layer 332 may be disposed between side parts of the light absorbing layer 324 and the second conductive semiconductor layer 326 exposed by the recess CH1 and the first electrode 342 and the first cover metal layer 352. By the first insulating layer 332 being disposed, the first electrode 342 and the first cover metal layer 352 may be electrically separated from the side parts of the light absorbing layer 324 and the second conductive semiconductor layer 326.

The first cover metal layer 352 may be disposed to surround the first electrode 342. The second cover metal layer 354 may be disposed to surround the second electrode 344.

The first and second cover metal layers 352 and 354 may each be made of a material with good electrical conductivity. For example, the first and second cover metal layers 352 and 354 may selectively contain, but are not limited to, at least one material selected from the group consisting of Ti, Au, Ni, In, Co, W, Fe, Rh, Cr, and Al.

In some cases, the first and second cover metal layers 352 and 354 may be omitted.

As shown in FIGS. 17 to 20, the semiconductor elements 300A, 300B, and 300C may have a horizontal bonding structure, but the embodiments are not limited thereto.

A semiconductor element 400 having a flip-chip bonding structure will be described below.

FIG. 21 shows a sectional view of the semiconductor element 400 having the flip-chip bonding structure according to an embodiment.

The semiconductor element 400 shown in FIG. 21 may include the semiconductor element 300A shown in FIG. 18, first and second pads 372 and 374, first and second electrode pads 382 and 384, first and second lead frames 402 and 404, and first and second insulating parts 412 and 414. Here, the first and second electrode pads 382 and 384 will be omitted.

Since the semiconductor element 300A included in the semiconductor element 400 shown in FIG. 21 is the same as the semiconductor element shown in FIG. 18, the same reference numerals are used, and a detailed description thereof will be omitted.

The first pad 372 may be electrically connected to the first electrode 342 through the first cover metal layer 352, and the second pad 374 may be electrically connected to the second electrode 344 through the second cover metal layer 354.

Also, the first pad 372 serves to electrically connect the first electrode 342 to the first lead frame 402, and the second pad 374 serves to electrically connect the second electrode 344 to the second lead frame 404.

Also, the first and second insulating parts 412 and 414 may be disposed between the first and second lead frames 402 and 404 to electrically isolate the first and second lead frames 402 and 404 from each other.

The second insulating layer 334 may be disposed between the first pad 372 and the second cover metal layer 354 to electrically isolate the first pad 372 and the second cover metal layer 354 from each other.

The second insulating layer 334 may be disposed on all surfaces of the semiconductor structure 320 while exposing an upper portion of the first cover metal layer 352 to which the first pad 372 is connected and an upper portion of the second cover metal layer 354 to which the second pad 374 is connected. Accordingly, it can be seen from FIG. 17 that the first cover metal layer 352 and the second cover metal layer 354 are partially exposed by the second insulating layer 334. Also, it can be seen from FIG. 19 that the first cover metal layers 352-1 to 352-4 are partially exposed by the second insulating layer 334, and it can be seen from FIG. 20 that the first cover metal layers 352-1 to 352-9 are partially exposed by the second insulating layer 334.

The first and second insulating layers 332 and 334 and the first and second insulating parts 412 and 414 may be made of the same material or different materials. Also, each of the first and second insulating layers 332 and 334 and the first and second insulating parts 412 and 414 may be made of a nonconductive oxide or nitride and may be made of, for example, a silicon oxide (Selective alloy) layer, an oxynitride layer, an Al₂O₃ layer, or an aluminum oxide layer, but the embodiments are not limited thereto.

Since the semiconductor element 400 shown in FIG. 21 has the flip-chip bonding structure unlike the semiconductor element 300A having the horizontal bonding structure shown in FIG. 18, light from an external source is incident onto the light absorbing layer 324 through the substrate 310 and the first conductive semiconductor layer 322. To this end, the substrate 310 and the first conductive semiconductor layer 322 are made of a transparent material, and the second conductive semiconductor layer 326, the first electrode 342, and the second electrode 344 may be made of transparent or non-transparent material.

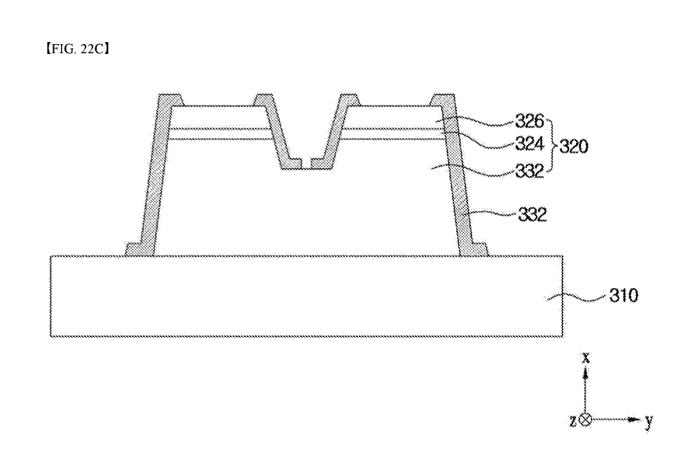

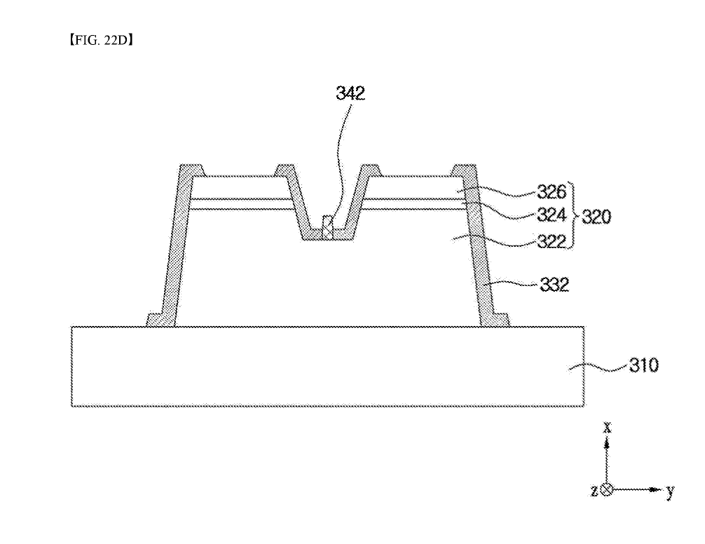

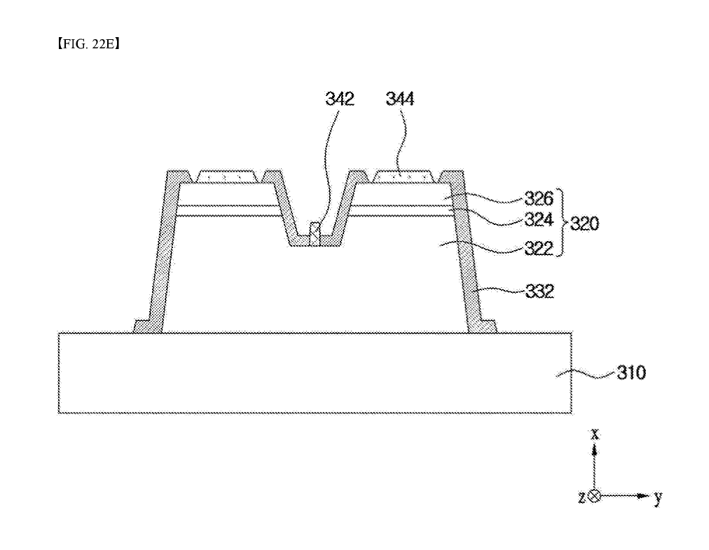

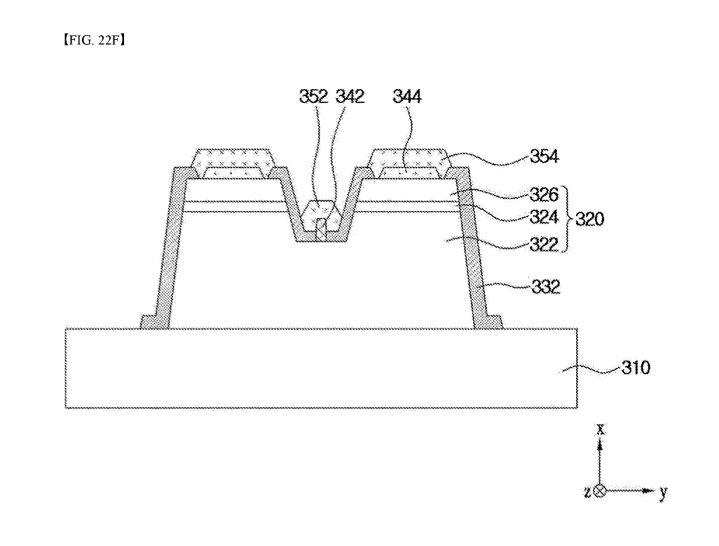

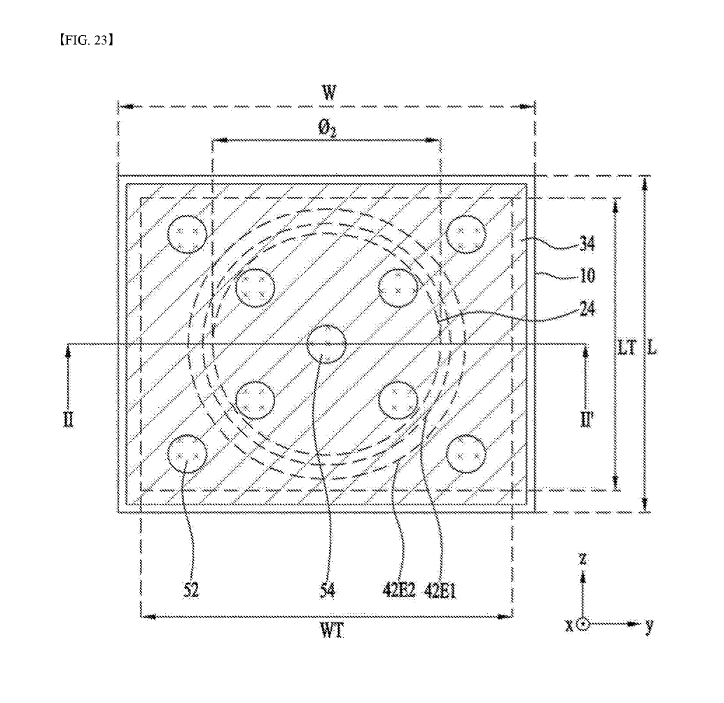

A method of manufacturing the semiconductor element 300A according to an embodiment shown in FIGS. 17 and 18 will be described below with reference to FIGS. 22A to 22F, but the embodiments are not limited thereto. That is, the semiconductor element 300A shown in FIGS. 17 and 18 may be manufactured by a method different from the manufacturing method shown in FIGS. 22A to 22F. Also, the semiconductor elements 300B and 300C shown in FIGS. 19 and 20 may be manufactured by the method illustrated in FIGS. 22A to 22F, except for different locations and number of recesses.

FIGS. 22A to 22F are processing sectional views illustrating a method of manufacturing the semiconductor element 300A according to an embodiment.

Referring to FIG. 22A first, a semiconductor structure 320 is formed over a substrate 310. In detail, a first conductive semiconductor layer 322 is formed over the substrate 310, and a light absorbing layer 324 is formed over the first conductive semiconductor layer 322. Subsequently, a second conductive semiconductor layer 326 is formed over the light absorbing layer 324.

Subsequently, referring to FIG. 22B, a first recess CH1 is formed to expose the first conductive semiconductor layer 322 through the second conductive semiconductor layer 326 and the light absorbing layer 324. FIG. 22B may be obtained by a typical photograph etching process. That is, the recess CH1 illustrated in FIG. 22B may be formed by placing an etching mask (not shown) in an area other than an area in which the first recess CH1 is to be formed, etching the semiconductor structure 320 using the etching mask to form the first recess CH1, and striping the etching mask.

Subsequently, referring to FIG. 22C, a first insulating layer 332 is formed on all surfaces of the semiconductor structure while an area in which a first electrode is to be disposed in the recess CH1 and an area in which a second electrode is to be disposed over the second conductive semiconductor layer 326 are exposed.

Subsequently, referring to FIG. 22D, a first electrode 342 is formed in the recess CH1 and over the exposed first conductive semiconductor layer 322 that is not covered by the first insulating layer 332.

Subsequently, referring to FIG. 22E, a second electrode 344 is formed over the exposed second conductive semiconductor layer 326 that is not covered by the first insulating layer 332.

Subsequently, referring to FIG. 22F, a first cover metal layer 352 surrounding the first electrode 342 and a second cover metal layer 354 surrounding the second electrode 344 are formed.

The following description will be provided with reference to a drawing including a semiconductor element according to a comparative example and a semiconductor element according to an embodiment.

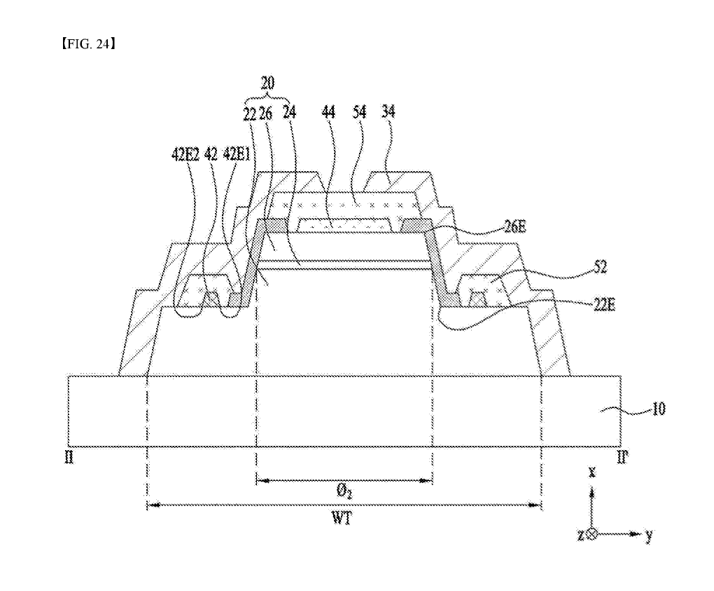

FIG. 23 shows a plan view of a semiconductor element according to a comparative example, and FIG. 24 shows a sectional view of the semiconductor element according to the comparative example taken along line II-II′ shown in FIG. 23.

The semiconductor element according to the comparative example and shown in FIGS. 23 and 24 includes a substrate 10, a substrate 10, a semiconductor structure 20, a second insulating layer 34, and first and second electrodes 42 and 44, and first and second cover metal layers 52 and 54. Here, the substrate 10, the semiconductor structure 20, the second insulating layer 34, the first and second electrodes 42 and 44, and the first and second cover metal layers 52 and 54 perform the same roles as the substrate 310, the semiconductor structure 20, the second insulating layer 34, the first and second electrodes 42 and 44, and the first and second cover metal layers 352 and 354, and thus a redundant description thereof will be omitted. That is, a first conductive semiconductor layer 22, a second conductive semiconductor layer 26, and a light absorbing layer 24 included in the semiconductor structure 20 perform the same roles as the first conductive semiconductor layer 322, the second conductive semiconductor layer 326, and the light absorbing layer 324 shown in FIG. 18, respectively.

The semiconductor elements 300A, 300B, 300C, and 400 according to embodiments and shown in FIGS. 17 and 21 have a planar shape in which the light absorbing layer 324 surrounds the first electrode 342. On the other hand, the semiconductor element according to the comparative example and shown in FIGS. 23 and 24 has a planar shape in which the first electrode 42 surrounds the light absorbing layer 24. Except for these differences, the semiconductor element according to the comparative example and shown in FIGS. 23 and 24 is the same as the semiconductor elements 300A, 300B, and 300C according to the embodiments, and thus a repetitive description thereof will be omitted.

On the other hand, the semiconductor element according to the comparative example and shown in FIGS. 23 and 24 has a planar shape in which the first electrode 42 surrounds the light absorbing layer 24. In this case, a third planar area A3 of the light absorbing layer 24 may be smaller than a fourth planar area A4, which is the entire planar area of the first conductive semiconductor layer 22 minus the third planar area A3. Here, the third planar area A3 may be expressed using the following Equation 1, and the fourth planar area A4 may be expressed using the following Equation 2.

$$\begin{matrix}A 3 = π \times {( \frac{{Φ}_{2}}{2} )}^{2} & [ Equation 1 ] \\ A 4 = LT \times WT - A 3. & [ Equation 2 ]\end{matrix}$$

Here, φ2 indicates the diameter of the light absorbing layer 24 with a circular planar shape, WT indicates the width of the first conductive semiconductor layer 22 in a second direction, and LT indicates the length of the first conductive semiconductor layer 22 in a third direction. Here, the third direction may be different from and orthogonal to the first and second directions For example, when the first direction is an x direction and the second direction is a y-axis direction, the third direction may be a z direction.

The first planar area A1 may be expressed using the following Equation 3, and the second planar area A2 may be expressed using the following Equation 4.

$$\begin{matrix}A 1 = LT \times WT - π \times {( \frac{{Φ}_{1}}{2} )}^{2} & [ Equation 3 ] \\ A 2 = π \times {( \frac{{Φ}_{1}}{2} )}^{2} & [ Equation 4 ]\end{matrix}$$

Here, φ1 indicates a distance between portions of the light absorbing layer 24 in a recess having a circular planar shape, WT indicates a width of the first conductive semiconductor layer 22 in the second direction, and LT indicates a length of the first conductive semiconductor layer 22 in the third direction.

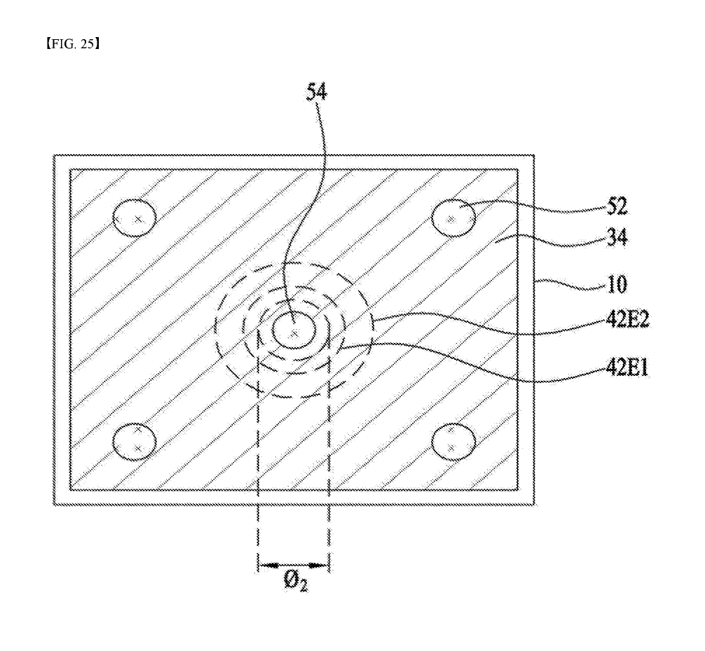

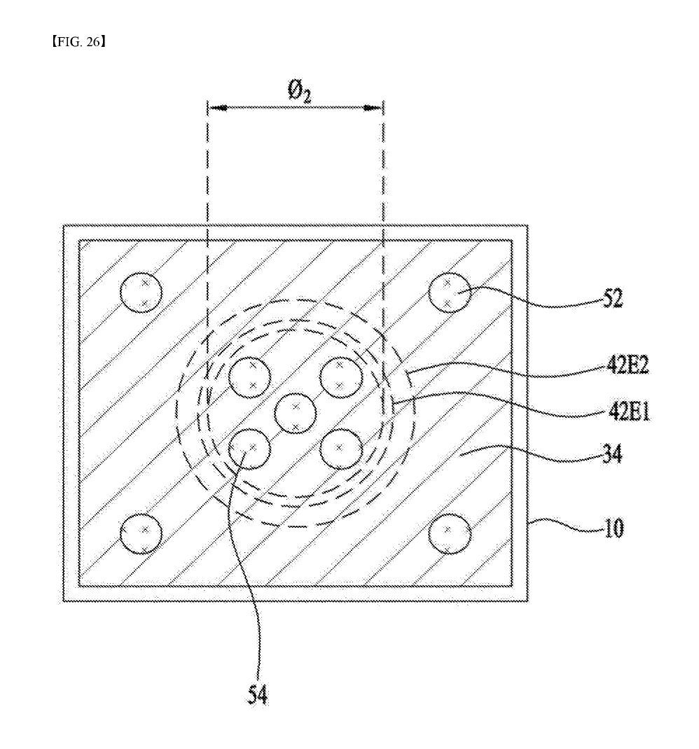

FIGS. 25 and 26 show a plan view of a semiconductor element according to another example.

The diameter φ2 of the light absorbing layer 24 shown in FIG. 25 is smaller than the diameter φ2 of the light absorbing layer 24 shown in FIG. 26, and the diameter φ2 of the light absorbing layer 24 shown in FIG. 26 is smaller than the diameter φ2 of the light absorbing layer 24 shown in FIG. 23. Except for a different number and locations of the second cover metal layers 54 and a different diameter φ2 of the light absorbing layer 24, the semiconductor element shown in FIGS. 25 and 26 may be the same as the semiconductor element shown in FIGS. 23 and 24, and thus the same reference numerals are used for the same parts. Accordingly, a repetitive description of the semiconductor element shown in FIGS. 25 and 26 will be omitted.

FIG. 27 is a graph showing a change in photocurrent by wavelength in the semiconductor element according to the comparative example. Here, a transverse axis indicates wavelengths, and a longitudinal axis indicates photocurrents.

The results as shown in FIG. 27 were obtained by measuring the photocurrent by wavelength while changing the diameter φ2 of the light absorbing layer 24 in the semiconductor element having both of a width W in the second direction and a length L in the third direction being 1100 μm, in FIGS. 23, 35, and 26. In this case, the width WT of the first conductive semiconductor layer 22 in the second direction and the length LT of the first conductive semiconductor layer 22 in the third direction were set to 1100 μm. In this case, the third and fourth planar areas A3 and A4 corresponding to the change in diameter φ2 are as following Table 1.

TABLE 1

| Category | FIG. 23 | FIG. 25 | FIG. 26 |
|---|---|---|---|
| Diameter (φ2) (cm) | 0.1 | 0.04 | 0.07 |
| A3 (cm²) | 7.85 × 10⁻³ | 1.26 × 10⁻³ | 3.85 × 10⁻³ |
| A4 (cm²) | 4.25 × 10⁻³ | 10.84 × 10⁻³ | 8.25 × 10⁻³ |

Referring to FIG. 27, it can be seen that a photocurrent C2 of the semiconductor element shown in FIG. 26 is greater than a photocurrent C3 of the semiconductor element shown in FIG. 25 with respect to a wavelength of about 270 nm and a photocurrent C1 of the semiconductor element shown in FIG. 23 is greater than the photocurrent C2 of the semiconductor element shown in FIG. 26. That is, it can be seen that the photocurrent increases as the diameter φ2 of the light absorbing layer 24 increases. The increase in the photocurrent may denote that the sensing sensitivity of a semiconductor element increases.

Also, the first and second planar areas A1 and A2 were found as the following table 2 while changing a distance φ1 between portions of the light absorbing layer 24 in the recess of the semiconductor elements 300A and 300B with a width Win the second direction and a length L in the third direction being 1100 μm, in FIGS. 17 and 20. In this case, the width WT of the first conductive semiconductor layer 322 in the second direction and the length LT of the first conductive semiconductor layer 322 in the third direction were set to 1100 μm. Also, in this case, the diameter φ0 of the exposed first cover metal layer 352 that is not covered by the second insulating layer 334 was regarded as the diameter φ1.

TABLE 2

| Category | FIG. 17 | FIG. 20 |
|---|---|---|
| Diameter (φ1) (cm) | 0.001 | 0.015 |
| A1 (cm²) | 12.1 × 10⁻³-0.785 × | 10.51 × 10⁻³ |
| | 10⁻⁶ | |
| A2 (cm²) | 0.785 × 10⁻⁶ | 1.59 × 10⁻³ |

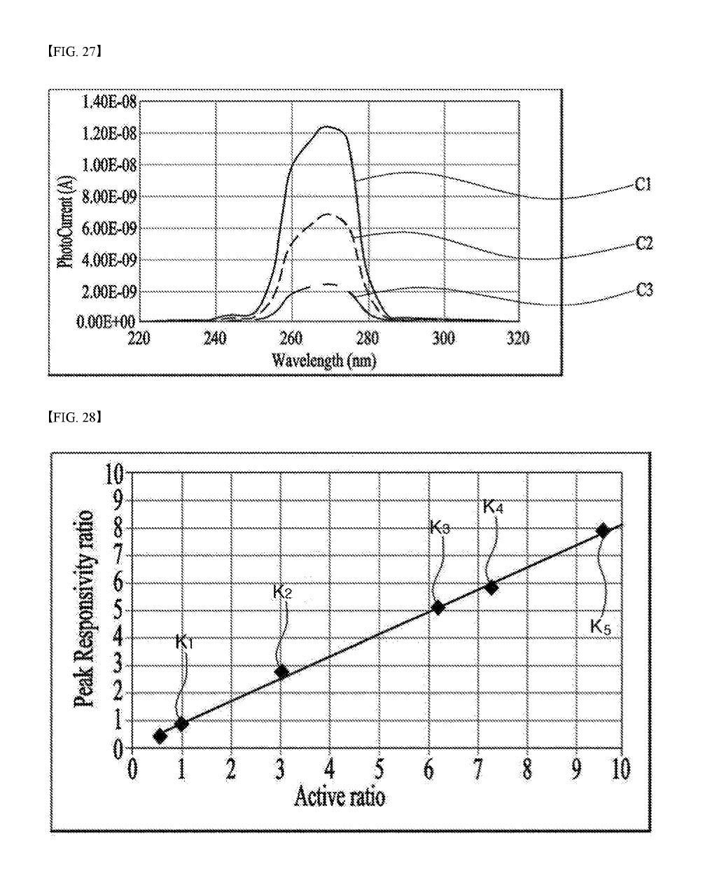

FIG. 28 is a graph showing a peak response ratio corresponding to an active ratio and illustrates different peak response ratios K2, K3, K4, and K5 with reference to the lowest peak response ratio K1. That is, the peak response ratios K2 to K5 correspond to a peak response ratio when the peak response ratio K1 is “1,”

Referring to FIG. 28, it can be seen that the peak response ratio K1 is smallest when the third planar area A3 of the light absorbing layer is smallest as shown in FIG. 25, the peak response ratio K2 slightly increases when the third planar area A3 of the light absorbing layer 24 increases as shown in FIG. 26, and the peak response ratio K3 further increases when the third planar area A3 of the light absorbing layer 24 further increases as shown in FIG. 23. Also, the peak response ratio K4 increases over the peak response ratios K1, K2, and K3 according to the comparative example when the first planar area A1 of the light absorbing layer 24 increases as in the embodiment 300C shown in FIG. 20, and the peak response ratio K5 becomes maximum when the first planar area A1 of the light absorbing layer 24 further rises as in the embodiment 300A shown in FIG. 17.

Referring to Table 1, for the semiconductor element according to the comparative example, the maximum third planar area A3 of the light absorbing layer 24 is 7.85×10⁻³ cm², which is about 64.87% of the entire planar area LT×WT of the first conductive semiconductor layer 22, i.e., 12.1 cm². On the other hand, according to an embodiment, it can be seen that the first planar area A1 of the light absorbing layer 324 is greater than 64.87%. For example, referring to Table 2, the first planar area A1 shown in FIG. 20 is 10.51 cm², which is about 86.85% of the entire planar area of the first conductive semiconductor layer 322, i.e., 12.1 cm². According to an embodiment, a ratio of the first planar area A1 of the light absorbing layer 324 to the entire planar area of the first conductive semiconductor layer 322 may be greater than 64.87%.

As a result, as the planar area of the light absorbing layer 324 increases, the semiconductor elements 300A, 300B, and 300C according to embodiments have a higher photocurrent with respect to the same chip area L×W than that in the comparative example. That is, the semiconductor elements 300A, 300B, and 300C according to the embodiments have higher sensing sensitivity than the semiconductor element according to the comparative example. This is a case in which the semiconductor elements 300A, 300B, and 300C according to the embodiments operate in a photovoltaic mode.

Further, the degree of freedom of designing the semiconductor elements 300A, 300B, and 300C more increases when the light absorbing layer 324 has a planar shape surrounding a recess according to an embodiment than when a semiconductor element according to the comparative example in which the first electrode 342 surrounds the light absorbing layer 324 is manufactured. That is, the arrangement (or locations) and/or number of recesses may be designed in various ways.

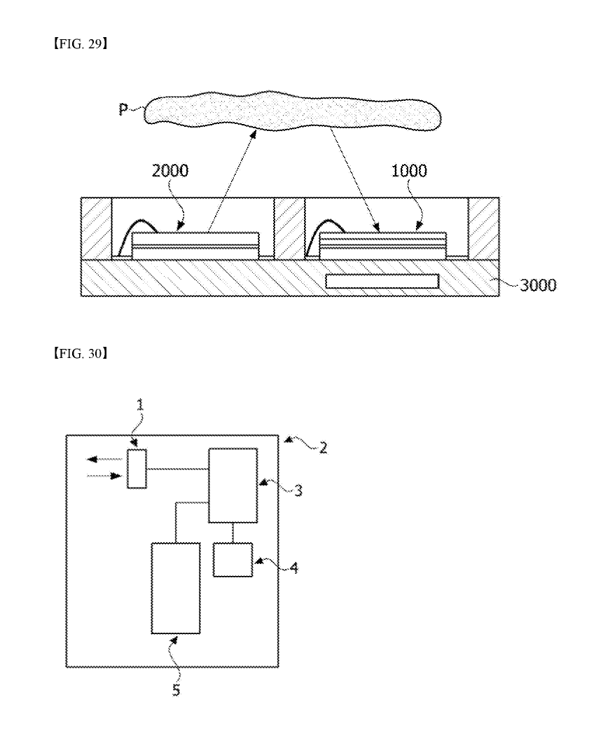

FIG. 29 is a diagram showing a sensor according to an embodiment.

Referring to FIG. 29, a sensing sensor according to an embodiment includes a housing 3000, a light emitting element 2000 disposed on the housing 3000, and a semiconductor element 1000 disposed on the housing 3000. Here, the semiconductor element 1000 may be the aforementioned semiconductor element according to the embodiment.

The housing 3000 may include a circuit pattern (not shown) that is electrically connected to the ultraviolet light emitting element 2000 and the semiconductor element 1000. The housing 3000 is not particularly limited as long as the housing 3000 is configured to electrically connect an external power source to an element.

The housing 3000 may include a control module (not shown) and/or a communication module (not shown). Accordingly, it is possible to miniaturize the sensor. The control module may apply power to the ultraviolet light emitting element 2000 and the semiconductor element 1000, amplify a signal detected by the semiconductor element 1000, or transmit the detected signal to the outside. The control module may be a field-programmable gate array (FPGA) or an application-specific integrated circuit (ASIC), but the present invention is not limited thereto.

The light emitting element 2000 may output light in an ultraviolet wavelength range to the outside of the housing 3000. The light emitting element 2000 may output near-ultraviolet wavelength light (UV-A), output far-ultraviolet wavelength light (UV-B), and emit deep-ultraviolet wavelength light (UV-C). The ultraviolet wavelength range may be determined by the Al composition of the light emitting element 2000. For example, the UV-A may have a wavelength ranging from 320 nm to 420 nm, the UV-B may have a wavelength ranging from 280 nm to 320 nm, and the UV-C may have a wavelength ranging from 100 nm to 280 nm.

There may be various microorganisms in the outside air. A microorganism P may be a biological particle including fungi, germs, bacterium, and the like. That is, the microorganism P may be distinguished from non-biological particles such as dust. the microorganism P generates unique fluorescence when strong energy is absorbed.

For example, the microorganism P may absorb light in a predetermined wavelength band and emit a fluorescence spectrum in a predetermined wavelength band. That is, the microorganism P consumes a portion of the absorbed light and emits a fluorescence spectrum in a certain wavelength band.

Thus, the semiconductor element 1000 detects the fluorescence spectrum emitted by the microorganism P. A microorganism P emits a different fluorescence spectrum. Thus, by examining the fluorescence spectrum emitted by the microorganism P, it is possible to find the presence and type of the microorganism P.

Here, the light emitting element 2000 may be a UV light emitting diode, and the semiconductor element 1000 may be the semiconductor element according to the above embodiment, i.e., a UV photodiode.

FIG. 30 is a conceptual view showing an electronic product according to an embodiment.

Referring to FIG. 30, the electronic product according to the embodiment includes a case 2, a sensing sensor 1 disposed in the case 2, a function unit 5 configured to perform the function of the product, and a control unit 3.

The electronic product may conceptually include a variety of home appliances and the like. For example, the electronic product may be a home appliance, such as a refrigerator, an air purifier, an air conditioner, a water purifier, a humidifier, etc., which receives power and performs a predetermined role.

However, the present invention is not limited thereto, and the electronic product may include a product having a predetermined closed space, such as an automobile. That is, the electronic product may conceptually include all the various products that need to confirm the presence of microorganisms.

The function unit 5 may perform the main function of the electronic product. For example, when the electronic product is an air conditioner, the function unit 5 may be a part that controls air temperature. Also, when the electronic product is a water purifier, the function unit 5 may be a part that purifies water.

The control unit 3 may communicate with the function unit 5 and the sensing sensor 1. The control unit 3 may operate the sensing sensor 1 to detect the presence and type of microorganisms introduced into the case 2. As described above, the sensing sensor 1 according to the embodiment can be miniaturized in the form of a module, and thus may be installed in electronic products of various sizes.

The control unit 3 may detect the concentration and type of the microorganisms by comparing the signal detected by the sensing sensor 1 to data stored in advance. The stored data may be stored in a memory in the form of a look-up table and periodically updated.

When the concentration of the microorganisms is greater than or equal to a predetermined reference value, the control unit 3 may operate a cleaning system or may output a warning signal to a display unit 4.

While the present invention has been described with reference to embodiments, these are just examples and do not limit the present invention. It will be understood by those skilled in the art that various modifications and applications may be made therein without departing from the essential characteristics of the embodiments. For example, elements described in the embodiments above in detail may be modified and implemented. Furthermore, differences associated with such modifications and applications should be construed as being included in the scope of the present invention defined by the appended claims.

1-10. (canceled)

11. A semiconductor element comprising:
a substrate; and
a semiconductor structure disposed on the substrate,
wherein the semiconductor structure comprises:
a first conductive semiconductor layer;
a second conductive semiconductor layer;
a first electrode disposed on and electrically connected to the first conductive semiconductor layer;
a second electrode disposed on and electrically connected to the second conductive semiconductor layer; and
a light absorbing layer disposed between the first conductive semiconductor layer and the second conductive semiconductor layer, and
wherein the light absorbing layer has a ratio of an outer length of an upper surface to an area of the upper surface, the ratio ranging from 1.2 to 1.5.

12. The semiconductor element of claim 11, wherein the upper surface of the light absorbing layer is circular, and
wherein the semiconductor element further comprises a filter layer between the substrate and the first conductive semiconductor layer.

13. The semiconductor element of claim 11, wherein a minimum distance between the first electrode and the upper surface of the light absorbing layer is 5 um or greater.

14. The semiconductor element of claim 11, wherein an upper surface of the second electrode has the same area as an upper surface of the second conductive semiconductor layer, and
wherein the first electrode is spaced apart from the light absorbing layer and surrounds the light absorbing layer.

15. The semiconductor element of claim 11, further comprising an insulating layer disposed on the first electrode and the second electrode,
wherein the insulating layer comprises:
a first recess disposed on the first electrode;
a second recess disposed on the second electrode;
a first pad disposed in the first recess and electrically connected to the first electrode; and
a second pad disposed in the second recess and electrically connected to the second electrode,
wherein the second pad does not overlap the first electrode in a thickness direction of the semiconductor structure, and
wherein the first pad is partially disposed on the first electrode to overlap the first electrode in the thickness direction of the semiconductor structure.

16. The semiconductor element of claim 11, wherein a lower surface of the second electrode and an upper surface of the second conductive semiconductor layer are coplanar with each other.

17. The semiconductor element of claim 11, further comprising:
a buffer layer disposed between the substrate and the semiconductor structure; and
an amplification layer disposed between the light absorbing layer and the first conductive semiconductor layer.

18. The semiconductor element of claim 17, wherein the amplification layer is an unintentionally doped semiconductor layer.

19. The semiconductor element of claim 17, wherein the amplification layer has the highest electric field in the semiconductor structure.

20. The semiconductor element of claim 11, further comprising at least one contact hole configured to expose the first conductive semiconductor layer through the second conductive semiconductor layer and the light absorbing layer.

21. The semiconductor element of claim 20, wherein the light absorbing layer has a planar shape surrounding the at least one contact hole.

22. The semiconductor element of claim 20, wherein a ratio of a first planar area of the light absorbing layer to an entire planar area of the first conductive semiconductor layer is greater than 64.87%.

23. The semiconductor element of claim 20, wherein the semiconductor element operates as a photovoltaic cell.

24. The semiconductor element of claim 20, further comprising:
a first insulating layer disposed between the first electrode and side portions of the light absorbing layer and the second conductive semiconductor layer exposed in the at least one contact hole;
a first cover metal layer disposed to surround the first electrode; and
a second cover metal layer disposed to surround the second electrode.

25. The semiconductor element of claim 24, further comprising:
a first pad connected to the first electrode through the first cover metal layer; and
a second pad connected to the second electrode through the second cover metal layer.

26. The semiconductor element of claim 25, further comprising a second insulating layer disposed between the first pad and the second cover metal layer, configured to open upper portions of the first cover metal layer and the second cover metal layer to which the first pad and the second pad are to be connected, and disposed on all surfaces of the semiconductor structure.

27. The semiconductor element of claim 20, wherein the first electrode is disposed in the at least one contact hole.

28. The semiconductor element of claim 20, wherein the at least one contact hole has a circular, elliptical or polygonal planar shape.

29. The semiconductor element of claim 11, wherein the semiconductor structure comprises:
a central area disposed in an inner side of the light absorbing layer in the at least one contact hole positioned inside an edge; and
a peripheral area in which the light absorbing layer is disposed, the peripheral area more protruding than the central area and having a greater planar shape than the central area.

30. A sensor comprising:
a housing;
a first semiconductor element disposed in the housing and configured to emit ultraviolet light; and
a second semiconductor element disposed in the housing,
wherein the second semiconductor element comprises:
a substrate; and
a semiconductor structure disposed on the substrate,
wherein the semiconductor structure comprises:
a first conductive semiconductor layer;
a second conductive semiconductor layer; and
a light absorbing layer disposed between the first conductive semiconductor layer and the second conductive semiconductor layer, and
wherein the light absorbing layer has a ratio of a maximum outer length of an upper surface to a maximum area of the upper surface, the ratio ranging from 1.2 to 1.5.
